(19) United States
(12) Patent Application Publication
(10) Pub. No.: US 2026/0219312 A1
(43) Pub. Date: Jul. 30, 2026

(54) SEMICONDUCTOR DEVICE, METHOD OF CONTROLLING SEMICONDUCTOR DEVICE AND CONTROL PROGRAM OF SEMICONDUCTOR DEVICE

(71) Applicant: Renesas Electronics Corporation, Tokyo (JP)

(72) Inventor: Tadashi KAMEYAMA, Tokyo (JP)

(21) Appl. No.: 19/407,497

(22) Filed: Dec. 3, 2025

(30) Foreign Application Priority Data
Jan. 29, 2025 (JP) 2025-013232

(51) Int. Cl. G01R 31/28; G01R 31/319

(52) U.S. Cl. CPC G01R 31/2874; G01R 31/2879; G01R 31/31924

(57) ABSTRACT

To improve the temperature measurement accuracy of a semiconductor device. The semiconductor device includes a temperature sensor having a plurality of switches As, a first terminal couped to the temperature sensor via the switches As, a second terminal coupled to the temperature sensor via the switches As, a third terminal coupled to the temperature sensor via the switches As, and a fourth terminal coupled to the temperature sensor via switches As and being supplied with a predetermined voltage VCC. The fourth terminal is capable of coupling with the first terminal, the second terminal, and third terminal via the switches As.

### CROSS-REFERENCE TO RELATED APPLICATIONS

The disclosure of Japanese Patent Application No. 2025-013232 filed on Jan. 29, 2025, including the specification, drawings and abstract is incorporated herein by reference in its entirety.

### BACKGROUND

The present disclosure relates to a semiconductor device, a control method for a semiconductor device, and a control program for a semiconductor device.

There are disclosed techniques listed below.
[Patent Document 1] Japanese Unexamined Patent Application Publication No. 2017-198523

Patent Document 1 discloses a semiconductor device with a built-in temperature sensor. The semiconductor device of Patent Document 1 measures various voltage values to adjust the offset of the temperature sensor.

### SUMMARY

It is desired to improve the temperature measurement accuracy of the semiconductor device.

Other objects and novel features will become apparent from the description of this specification and the accompanying drawings.

According to one embodiment, the semiconductor device includes first to fourth terminals and a first temperature sensor. The first temperature sensor includes first to fourth switch units and a bandgap reference circuit. The first switch unit is configured to output a reference voltage generated based on the output of the bandgap reference circuit from the first terminal, the second switch unit is configured to output a PTAT voltage generated based on the output of the bandgap reference circuit, the third switch unit is configured to couple between the third terminal and at least one of the first terminal and the second terminal, and the fourth switch unit is configured to output, from the first to third terminals a predetermined voltage supplied to the first temperature sensor.

According to another embodiment, the method of controlling a semiconductor device including first to fourth terminals and a first temperature sensor, the first temperature sensor including a bandgap reference circuit and first to fourth switch units, the first switch unit being configured to output a reference voltage generated based on the output of the bandgap reference circuit from the first terminal, the second switch unit being configured to output a PTAT voltage generated based on the output of the bandgap reference circuit, the third switch unit being configured to connect between the third terminal and the first terminal or the second terminal, and the fourth switch unit being configured to output a predetermined voltage supplied to the first temperature sensor from the first to third terminals, the method controlling the semiconductor device, includes controlling the operation of the first to fourth switch units by a control unit.

According to one embodiment, the control program of a semiconductor device, the semiconductor device including first to fourth terminals and a first temperature sensor, the first temperature sensor including first to fourth switch units and a bandgap reference circuit, the first switch unit being configured to output a reference voltage generated based on the output of the bandgap reference circuit from the first terminal, the second switch unit being configured to output a PTAT voltage generated based on the output of the bandgap reference circuit, the third switch unit being configured to connect between the third terminal and the first terminal or the second terminal, and the fourth switch unit being configured to output a predetermined voltage supplied to the first temperature sensor from the first to third terminals, and the program causes the semiconductor device to perform to step of controlling the operation of the first to fourth switch units.

According to the embodiment, it is possible to improve the temperature measurement accuracy of the semiconductor device.

### BRIEF DESCRIPTION OF THE DRAWINGS

FIG. 1 is a configuration diagram illustrating a semiconductor device 101 according to a comparative example.

FIG. 2 is a graph illustrating the temperature characteristics of the reference voltage Vref1 and the PTAT voltage Vptat1 of the temperature sensor in the semiconductor device according to the comparative example.

FIG. 3 is a configuration diagram illustrating the state during measurement in the semiconductor device 101 according to comparative example.

FIG. 4 is a schematic configuration diagram illustrating a semiconductor device 1 according to the first embodiment.

FIG. 5 is a configuration diagram illustrating semiconductor device 1 according to the first embodiment and a test device ME for testing the semiconductor device 1.

FIG. 6 is a schematic diagram for explaining the first test of the semiconductor device according to the first embodiment.

FIG. 7 is a flowchart illustrating the operation of the first test in the semiconductor device according to the first embodiment.

FIG. 8 is a flowchart illustrating the operation of the first test in the semiconductor device according to the first embodiment.

FIG. 9 is a flowchart illustrating the operation of the first test in the semiconductor device according to the first embodiment.

FIG. 10 is a schematic diagram for explaining the test operation following the test operation shown in FIG. 6 regarding the first test of the semiconductor device according to the first embodiment.

FIG. 11 is a flowchart illustrating the test operation following FIGS. 7 to 9 of the semiconductor device according to the first embodiment.

FIG. 12 is a schematic diagram for explaining the test operation following the test operation shown in FIG. 10 regarding the first test of the semiconductor device according to the first embodiment.

FIG. 13 is a flowchart illustrating the test operation following the test operation of FIG. 11 of the semiconductor device according to the first embodiment.

FIG. 14 is a configuration diagram illustrating a semiconductor device 1 according to the first embodiment, showing route E1 related to the test operations shown in FIGS. 7 and 9.

FIG. 15 is a configuration diagram illustrating a semiconductor device 1 according to the first embodiment, showing route E1a related to the test operation shown in FIG. 11.

FIG. 16 is a configuration diagram illustrating a semiconductor device 1 according to the first embodiment, showing route E1b related to the test operations shown in FIGS. 7 to 9.

FIG. 17 is a configuration diagram illustrating a semiconductor device 1 according to the first embodiment, showing route E1c related to the test operation shown in FIG. 13.

FIG. 18 is a configuration diagram illustrating a semiconductor device 1 according to the first embodiment, showing route Eld related to the test operation shown in FIG. 11.

FIG. 19 is a configuration diagram illustrating a semiconductor device 1 according to the first embodiment, showing route Ele for measuring the reference voltage and PTAT voltage output by the bandgap reference circuit BGR of the temperature sensor at terminals Tr and Tp.

FIG. 20 is a configuration diagram illustrating a semiconductor device 1 according to the first embodiment, showing route Elf for measuring the reference voltage and PTAT voltage output by the bandgap reference circuit BGR at terminal Tt.

FIG. 21 is a schematic diagram for explaining the second test of the semiconductor device 1 according to the first embodiment.

FIG. 22 is a flowchart illustrating the test operation of the second test of the semiconductor device according to the first embodiment.

FIG. 23 is a flowchart illustrating the test operation of the second test of the semiconductor device according to the first embodiment.

FIG. 24 is a schematic diagram for explaining the test operation following the test operation shown in FIG. 21 regarding the second test of the semiconductor device 1 according to the first embodiment.

FIG. 25 is a flowchart illustrating the test operation following FIGS. 22 and 23 regarding the second test of the semiconductor device according to the first embodiment.

FIG. 26 is a flowchart illustrating the test operation following FIGS. 22 and 23 regarding the second test of the semiconductor device according to the first embodiment.

FIG. 27 is a schematic diagram for explaining the test operation following the test operation shown in FIG. 24 regarding the second test of the semiconductor device 1 according to the first embodiment.

FIG. 28 is a flowchart illustrating the test operation following FIGS. 25 and 26 regarding the second test of the semiconductor device according to the first embodiment.

FIG. 29 is a schematic diagram for explaining the test operation following the test operation shown in FIG. 27 regarding the second test of the semiconductor device 1 according to the first embodiment.

FIG. 30 is a flowchart illustrating the test operation following FIG. 28 regarding the second test of the semiconductor device according to the first embodiment.

FIG. 31 is a configuration diagram illustrating a semiconductor device 1 according to the first embodiment, showing route Fu related to the test operations shown in FIGS. 22 and 23.

FIG. 32 is a configuration diagram illustrating a semiconductor device 1 according to the first embodiment, showing route Fua related to the test operations shown in FIGS. 28 and 30.

FIG. 33 is a configuration diagram illustrating a semiconductor device 1 according to the first embodiment, showing the case of route Fub input to the temperature sensor.

FIG. 34 is a configuration diagram illustrating a semiconductor device 1 according to the first embodiment, showing route Fuc for measuring the reference voltage VREFu and PTAT voltage VPTATu of the temperature sensor THSu.

FIG. 35 is a flowchart illustrating the control method of the semiconductor device according to the first embodiment.

FIG. 36 is a configuration diagram illustrating a semiconductor device 2 according to embodiment 2.

FIG. 37 is a configuration diagram illustrating a semiconductor device 3 according to embodiment 3.

FIG. 38 is a diagram illustrating the resistor division ZR in the semiconductor device according to embodiment 3.

FIG. 39 is a block diagram illustrating the control unit CON in the semiconductor devices according to Embodiments 1 to 3.

### DETAILED DESCRIPTION

For clarity of explanation, the following description and drawings are appropriately omitted and simplified. In the drawings, the same elements are denoted by the same reference numerals, and a repetitive description thereof is omitted as necessary. Some reference numerals may be omitted to prevent the drawings from becoming complicated.

First, in “Comparative Example”, the semiconductor device according to the comparative example will be described. Subsequently, in “Problems Newly Found by the Inventor”, the problems newly found by the inventor regarding the semiconductor device of the comparative example will be described. Then, in “First Embodiment” to “Third Embodiment”, the semiconductor devices according to First Embodiment to Third Embodiment will be described in comparison with the comparative example. This will make the semiconductor device according to the present embodiment clear. It should be noted that the comparative example and the problems newly found by the inventor are also included in the scope of the technical idea of the embodiments.

### Comparative Example

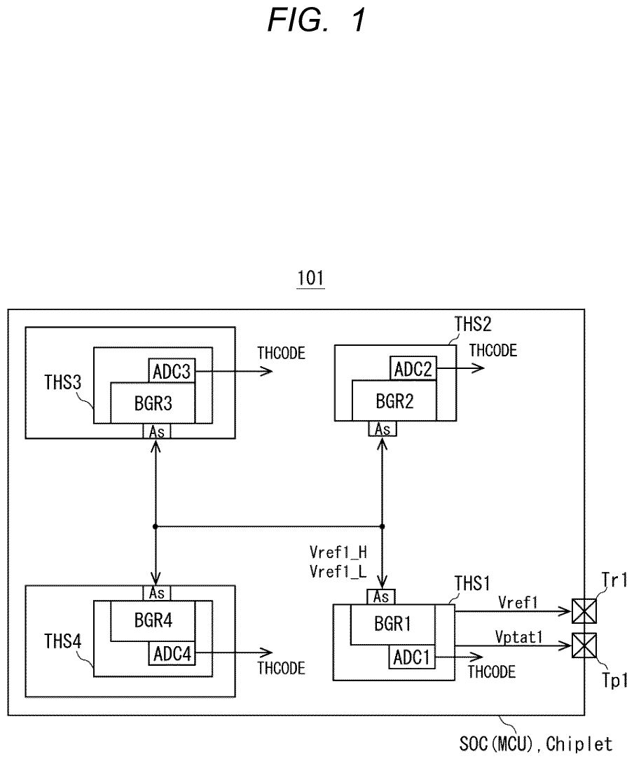

FIG. 1 is a configuration diagram illustrating a semiconductor device 101 according to a comparative example. As shown in FIG. 1, the semiconductor device 101 includes multiple temperature sensors (hereinafter a temperature sensor is sometimes referred to as thermal sensor or THS). The temperature sensor may be represented as THS or denoted as temperature sensor THS.

The plurality of temperature sensors THSs include, for example, four temperature sensors THS1 to THS4. It should be noted that the number of temperature sensors THSs, which is four, is just an example, and it may be three or fewer, or five or more. Each temperature sensor THS includes a bandgap reference circuit BGR, an AD converter (Analog to Digital Converter, hereinafter sometimes referred to as ADC), and a plurality of analog switches (hereinafter the analog switches are sometimes referred to as As or switches). For example, the temperature sensor THS1 includes a bandgap reference circuit BGR1, an AD converter ADC1, and an analog switch As. The temperature sensor THS2 includes a bandgap reference circuit BGR2, an AD converter ADC2, and an analog switch As. The temperature sensor THS3 includes a bandgap reference circuit BGR3, an AD converter ADC3, and an analog switch As. The temperature sensor THS4 includes a bandgap reference circuit BGR4, an AD converter ADC4, and an analog switch As.

The plurality of temperature sensors THSs may be formed in a System On a Chip (SoC), a Micro Controller Unit (MCU), and a Chiplet, etc. The semiconductor device 101, which is a System On a Chip (SoC), a Micro Controller Unit (MCU), and a Chiplet, etc., has external terminals Tr1 and Tp1.

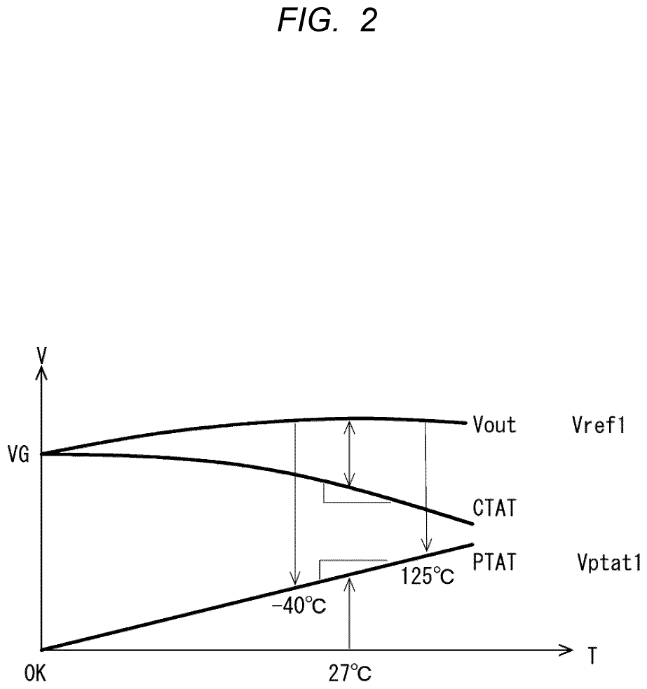

Each of the temperature sensors THSs, based on the output of the bandgap reference circuit BGR, generates a PTAT voltage Vptat and a reference voltage Vref. The AD converter ADC converts the PTAT voltage Vptat to an AD conversion value THCODE based on the reference voltage Vref. FIG. 2 is a graph illustrating the temperature characteristics of the reference voltage Vref1 and the PTAT voltage Vptat1 of the temperature sensor THS1 in the semiconductor device 101 according to a comparative example. The horizontal axis indicates temperature, and the vertical axis indicates voltage values. FIG. 2 shows the voltage Vout {bandgap reference Voltage}generated by the bandgap reference circuit BGR, the CTAT voltage (Complementary to Absolute Temperature Voltage), and the PTAT voltage Vptat (Proportional to Absolute Temperature Voltage). As shown in FIG. 2, the reference voltage Vref1 and the PTAT voltage Vptat1 in the temperature sensor THS1 have temperature characteristics. The voltage Vout corresponds to the reference voltage Vref described here. As shown in FIG. 2, the reference voltage Vref1 is almost independent of temperature. On the other hand, the PTAT voltage Vptat1 has a primary linear temperature dependency. By using such reference voltage Vref1 and PTAT voltage Vptat for AD conversion, digital values corresponding to temperature can be obtained. In other words, the AD converter ADC1 converts the PTAT voltage Vptat1 from an analog value to a digital value based on the reference voltage Vref1. The AD converters ADC2 to ADC4 convert the PTAT voltages Vptat2 to Vptat4 from analog values to digital values based on the reference voltages Vref2 to Vref4, respectively.

It is desirable that an error in the accuracy of temperature of each of the one or more temperature sensors THS mounted on the semiconductor device 101 be similarly small. Therefore, it is necessary to correct the temperature characteristics of each temperature sensor THS.

The temperature sensor THS1 has a generation circuit (not shown) that generates a voltage Vref1_H and a voltage Vref1_L by dividing the reference voltage Vref1. The voltage Vref1_H corresponds to the voltage value of the PTAT voltage Vptat1 when the temperature is the upper limit of the operating temperature range. The voltage Vref1_L corresponds to the voltage value of the PTAT voltage Vptat1 when the temperature is the lower limit of the operating temperature range. For example, the upper limit temperature of the operating temperature range is 125 degrees, and the lower limit temperature of the operating temperature range is −40 degrees. It should be noted that the upper limit temperature of the operating temperature range is not limited to 125 degrees, and the lower limit temperature of the operating temperature range is not limited to −40 degrees. In testing, the temperature sensor THS1 converts the voltages Vref1_H and Vref1_L to AD conversion values THCODE1_H and THCODE1_L, respectively, based on the reference voltage Vref1. The generated voltages Vref1_H and Vref1_L are measured via the external terminal Tp1. The reference voltage Vref1 is measured via the external terminal Tr1. Based on the AD conversion values THCODE1_H and THCODE1_L and the measured values of the voltages Vref1_H and Vref1_L, the temperature characteristics of temperature sensor THS1 are obtained.

Returning to FIG. 1, in testing, the voltages Vref1_H and Vref1_L generated by the temperature sensor THS1 are provided to the temperature sensors THS2 to THS4, respectively. The temperature sensor THS2 converts the voltages Vref1_H and Vref1_L supplied from the temperature sensor THS1 to AD conversion values THCODE2_H and THCODE2_L based on the reference voltage Vref2 of the temperature sensor THS2. Similarly, the temperature sensors THS3 and THS4 also output AD conversion values THCODE3_H, THCODE3_L, THCODE4_H, and THCODE4_L. The difference between the AD conversion values obtained by the temperature sensors THS1 and the AD conversion values THCODE obtained by the temperature sensors THS2 to THS4 is calculated.

As mentioned above, the reference voltage Vref1 is measured via the external terminal Tr1. On the other hand, the voltages Vref1_H and Vref1_L supplied from the temperature sensor THS1 to the temperature sensors THS2 to THS4 can be measured via the external terminal Tp1. Therefore, the reference voltages Vref of the temperature sensors THS2 to THS4 can be estimated from the difference between the AD conversion value of the temperature sensor THS1 and the AD conversion values of the temperature sensors THS2 to THS4, and the voltages measured at the external terminals Tr1 and Tp1. Once the voltage value of the reference voltage Vref of each temperature sensor THS is known, the PTAT voltage Vptat of each temperature sensor THS can be estimated. In this way, the temperature characteristics of the temperature sensors THS2 to THS4 are obtained. It should be noted that due to the characteristics of the reference voltage Vref, the voltages Vref1_H and Vref1_L are not affected by the temperature difference at the location of the temperature sensor THS, allowing the temperature characteristics of each temperature sensor THS to be obtained. Thus, tests are conducted to obtain the temperature characteristics of each temperature sensor THS, and based on the test results, temperature characteristic correction is performed.

The reason for using the voltages Vref1_H and Vfer1_L is that regardless of the temperature of the semiconductor device 101, such as a System On a Chip (SoC), in use, the characteristics of the temperature sensor THS at the guaranteed operating temperature limits of 125 degrees and −40 degrees can be obtained.

### Problems Newly Found by the Inventor

As described above, the temperature characteristics of the temperature sensor THS1 are confirmed based on the voltage measured via terminals Tr and Tp. However, if measurement errors are included in those measured values, the temperature characteristics of the temperature sensor THS1 may not be accurately obtained. Furthermore, the temperature sensors THS2 to THS4 are located in different places within the semiconductor device. Therefore, during testing, a temperature difference may occur between the temperature sensors THS2 to THS4. That is, the test conditions for the temperature sensors THS2 to THS4 are not necessarily identical.

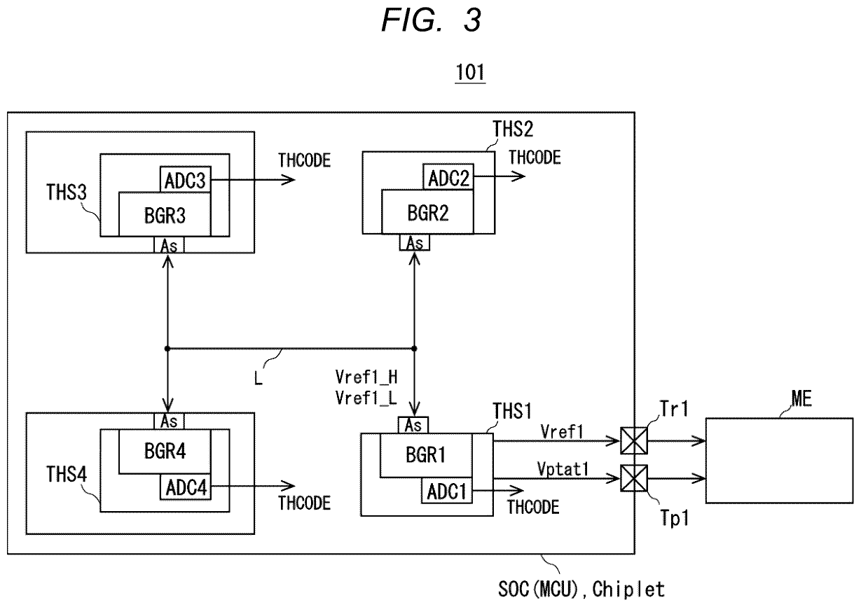

FIG. 3 is a configuration diagram illustrating the state during measurement in the semiconductor device 101 according to the comparative example. As shown in FIG. 3, during the measurement of various parameters of the semiconductor device 101, the test device ME is coupled to external terminals Tr1 and Tp1. The problems newly identified by the inventor are shown below.

### Measurement Error Due to Probe

In the test environment using the test device ME, the measurement error of the voltage at external terminals Tr1 and Tp1 affects the acquisition of the temperature characteristics of the temperature sensor THS. The measurement error is specifically caused by the contact resistance with the socket or probe when loading samples onto the tester board.

Impact of Voltage Drop due to Internal Wiring from Temperature Sensor THS1 to Temperature Sensor THSn

Each temperature sensor THS2 to THS4 receives the voltage Vref1_H or Vref1_L generated by the temperature sensor THS1 via signal lines and switch As. For example, only the switch As of the temperature sensor THS3 is turned ON, and the voltages Vref1_H and Vref1_L are supplied to the temperature sensor THS3.

The input to the temperature sensor THS is high impedance, but a slight voltage drop occurs.

Moreover, due to the long signal line L between the temperature sensors THSs, power supply noise during testing causes voltage fluctuations (voltage drop) due to wiring load (LCR). This affects the acquisition of temperature characteristics of each temperature sensor THS2 to THS4 as a measurement error.

Impact of the Power Supply Voltage Supplied to Each Temperature Sensor THSn when the Temperature Sensor THS1 is Used as a Reference

During testing, fluctuations occur in the GND level within the semiconductor device 101, such as a System on a Chip (SoC). For example, if the temperature sensor THS3 is formed within a Power supply voltage isolation (Poi) region (not shown) where the power supply voltage is separated from the temperature sensor THS1, the GND levels of temperature sensor THS1 and THS3 do not necessarily match. When the voltage Vref1_H and voltage Vref1_L generated by the temperature sensor THS1 are supplied to the temperature sensor THS3, for example, the supplied voltage causes a slight voltage difference in the temperature sensor THS3. Such a voltage difference affects the acquisition of temperature characteristics as a measurement error.

Thus, semiconductor device 101 of the comparative example is affected by at least one of the measurement errors related to external terminals Tr1 and Tp1, measurement errors related to signal line L, and measurement errors related to the GND level when obtaining temperature characteristics.

### Overview of First Embodiment

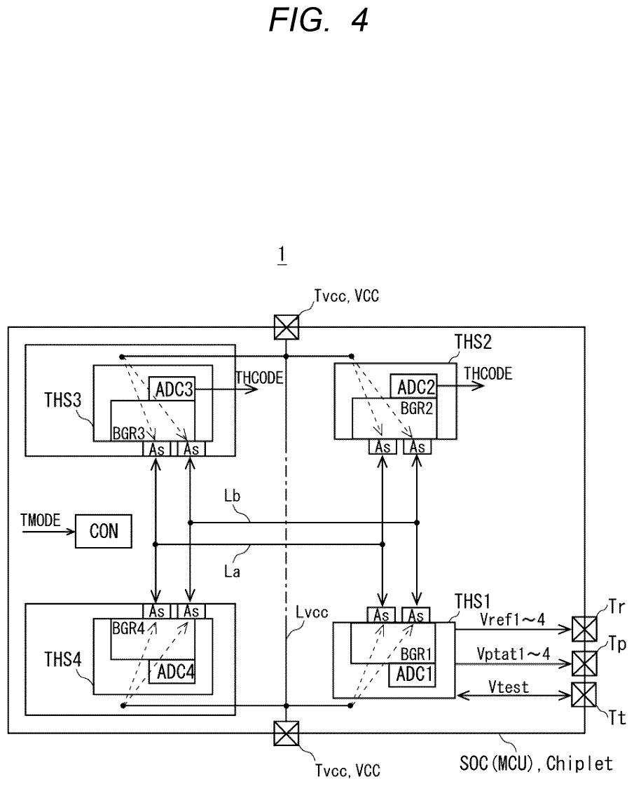

Next, the overview of the semiconductor device of this embodiment will be described. FIG. 4 is a schematic configuration diagram illustrating the semiconductor device 1 according to the first embodiment. As shown in FIG. 4, the semiconductor device 1 of this embodiment has external terminals Tr and Tp instead of the external terminals Tr1 and Tp1 of the semiconductor device 101 of the comparative example. Furthermore, the semiconductor device 1 has an external input terminal Tt. The external terminals Tr, Tp, and the external input terminal Tt may simply be referred to as terminal Tr, terminal Tp, and terminal Tt. Additionally, the semiconductor device 1 has a plurality of temperature sensors. In FIG. 4, four temperature sensors THS1 to THS4 are shown, but the number of temperature sensors is not limited to this. Each temperature sensor THS1 to THS4 is interconnected by signal line La. Additionally, each temperature sensor THS1 to THS4 is interconnected by signal line Lb. In this embodiment, only one terminal Tt is shown, but it is not limited to this; a plurality of terminals may be provided. The terminal Tr, the terminal Tp, and the terminal Tt can be regarded as the first terminal, second terminal, and third terminal, respectively. The signal line La can be regarded as the first signal line, and the signal line Lb can be regarded as the second signal line.

The semiconductor device 1 further includes a terminal Tvcc. The terminal Tvcc can be regarded as the fourth terminal. A predetermined voltage VCC is supplied to the terminal Tvcc. For example, the predetermined voltage VCC is the power supply voltage. The terminal Tvcc is coupled to each temperature sensor THS via switch As and wiring Lvcc. Furthermore, the semiconductor device 1 includes a control unit CON. The semiconductor device 1 may be a System on a Chip (SoC), a microcontroller unit (MCU), or a chiplet, similar to the semiconductor device 101.

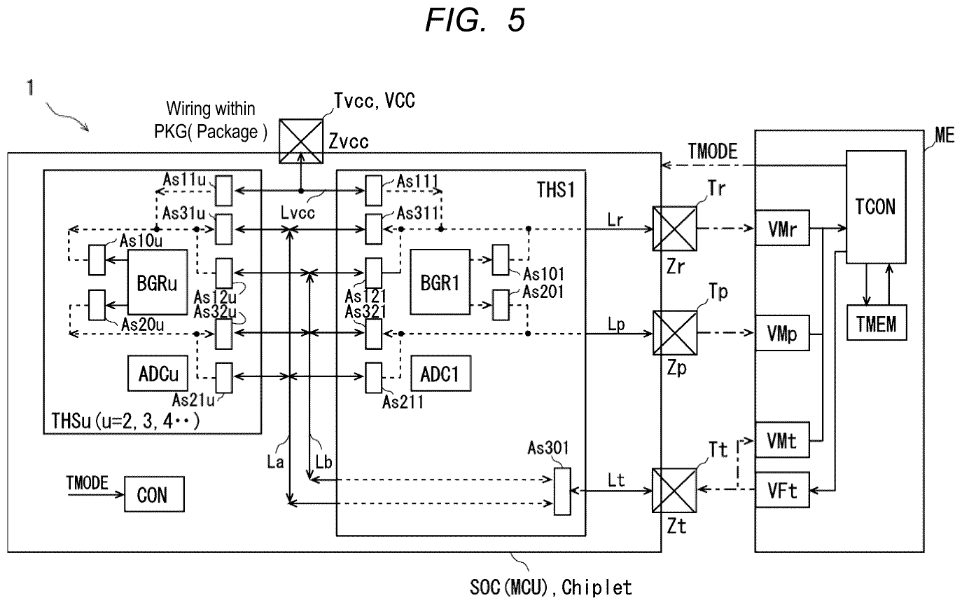

FIG. 5 is a configuration diagram illustrating the semiconductor device 1 according to the first embodiment and the test device ME for testing the semiconductor device 1. The semiconductor device 1 includes a temperature sensor THS1. Furthermore, the semiconductor device 1 includes temperature sensors THSu (u=2, 3, 4, etc.). That is, semiconductor device 1 means that it includes two or more temperature sensors THS2, THS3, THS4, etc.

The temperature sensor THS1 includes a bandgap reference circuit BGR1 and switches As101, As111, As121, As201, As211, As301, As311, and As321. The temperature sensor THS1 includes the first to fourth switch units, which will be described later. The control unit CON controls the on/off of these switches As.

The switch As101 turns on to output the reference voltage Vref from the bandgap reference circuit BGR1 from the terminal Tr (first terminal). The switch As101 constitutes the first switch unit. The first switch unit is provided to output the reference voltage Vref generated based on the output of the bandgap reference circuit BGR1 from the first terminal.

The switch As201 turns on to output the PTAT (Proportional To Absolute Temperature) voltage Vptat from the bandgap reference circuit BGR1 from terminal Tp. The switch As201 constitutes the second switch unit. The second switch unit is provided to output the PTAT voltage Vptat generated based on the output of the bandgap reference circuit BGR1.

The switch As301 is configured to connect a signal line La or a signal line Lb with the terminal Tt. The switch As111 is coupled at one end to terminal Tvcc and at the other end to the wiring connecting the switch As311 and the terminal Tr. The switch As121 is coupled at one end to the signal line Lb and at the other end to the wiring connecting the switch As311 and the terminal Tr. The switch As211 is coupled at one end to the signal line La and at the other end to the wiring between the switch As321 and the terminal Tp. The switch As311 is coupled at one end to the signal line La and at the other end to the terminal Tr. The switch As321 is coupled at one end to the signal line Lb and at the other end to the terminal Tp. The switches As301, As311, As121, As321, and As211 constitute the third switch unit. The third switch unit is provided to connect between the terminal Tt (the third terminal) and the terminal Tr or Tp (the first or the second terminal). The switch As111 constitutes the fourth switch unit. The fourth switch unit is provided to output the predetermined voltage supplied to temperature sensor THS1 from the first to third terminals.

Hereafter, the switches As101, As111, As121, As201, As211, As301, As311, and As321 may be collectively referred to as switch As within the temperature sensor THS1 without specific distinction. The switch As101 may also be referred to as the first switch unit. The switch As201 may also be referred to as the second switch unit. Furthermore, the switches As301, As311, As121, As321, and As211 may also be referred to as the third switch unit. The switch As111 may also be referred to as the fourth switch unit.

Thus, the semiconductor device 1 includes the temperature sensor THS1, the control unit CON that controls the temperature sensor THS1, and the first to third terminals (Tr, Tp, Tt). The temperature sensor THS1 includes the bandgap reference circuit BGR1 that outputs reference voltage Vref1 and PTAT voltage Vptat1 with primary linear temperature dependency, and an AD converter ADC1 that converts PTAT voltage Vptat1 from an analog value to a digital value based on reference voltage Vref1. The temperature sensor THS1 can be regarded as the first temperature sensor. The reference voltage Vref1 generated within temperature sensor THS1 can be regarded as the first reference voltage Vref. The PTAT voltage Vptat1 generated within temperature sensor THS1 can be referred to as the first detection voltage or the first PTAT voltage Vptat. Additionally, the AD converter ADC1 within temperature sensor THS1 can be regarded as the first AD converter ADC.

The temperature sensor THSu includes a bandgap reference circuit BGRu and switches As10u, As11u, As12u, As20u, As21u, As30u, As31u, and As32u. The temperature sensor THSu includes the fifth to eighth switch units, which will be described later. The control unit CON also controls the on/off of these switches As within the temperature sensor THSu.

The switch As10u is provided between the terminal that outputs the reference voltage Vrefu from the bandgap reference circuit BGRu and the switch As31u. The switch As10u constitutes the fifth switch unit. The fifth switch unit is provided to output the reference voltage Vref generated based on the output of the bandgap reference circuit BGRu from the first terminal.

The switch As11u is coupled at one end to the terminal Tvcc and at the other end to the wiring connecting the switch As10u and the switch As31u. The switch As11u constitutes the eighth switch unit. The eighth switch unit is provided to output the predetermined voltage supplied to the temperature sensor THS2 from the first to third terminals.

The switch As12u is coupled at one end to the signal line Lb and at the other end to the wiring connecting the switch As10u and the switch As31u.

The switch As20u is provided between the terminal that outputs the PTAT voltage Vptat from the bandgap reference circuit BGRu and the switch As32u. The switch As20u constitutes the sixth switch unit. The sixth switch unit is provided to output the PTAT voltage Vptat generated based on the output of the bandgap reference circuit BGRu.

The switch As21u is coupled at one end to the signal line La and at the other end to the wiring between the switch As20u and the switch As32u. The switch As31u is coupled at one end to the signal line La and at the other end to the wiring connecting the switch As10u and the switch As31u. The switch As32u is coupled at one end to the signal line Lb and at the other end to the switch As20u. The switches As30u, As31u, As12u, As32u, and As21u constitute the seventh switch unit. The seventh switch unit is provided to connect between the third terminal and either the first terminal or the second terminal.

Hereafter, the switches As10u, As11u, As12u, As20u, As21u, As30u, As31u, and As32u may be collectively referred to as switch As within the temperature sensor THSu without specific distinction. Additionally, the switch As10u may be referred to as the fifth switch unit. The switch As20u may also be referred to as the sixth switch unit. Furthermore, the switches As30u, As31u, As12u, As32u, and As21u may be referred to as the seventh switch unit. The switch As11u may be referred to as the eighth switch unit.

Thus, semiconductor device 1 further includes the temperature sensor THSu and the signal lines La and Lb. The temperature sensor THSu includes the bandgap reference circuit BGRu that outputs the reference voltage Vrefu and the PTAT voltage Vptatu with primary linear temperature dependency, and an AD converter ADCu that converts the PTAT voltage Vptatu from an analog value to a digital value based on the reference voltage Vrefu. The temperature sensor THSu can be regarded as the second temperature sensor. The reference voltage Vrefu generated within the temperature sensor THSu can be regarded as the second reference voltage Vref. The PTAT voltage Vptatu generated within the temperature sensor THSu may also be referred to as the second detection voltage or the second PTAT voltage Vptat. Additionally, the AD converter within the temperature sensor THSu can be regarded as the second AD converter ADC.

The signal lines La and Lb are wiring that couples temperature sensor THS1 with each of the temperature sensors THS2 to THS4.

The semiconductor device 1 is coupled to the test device ME for testing. The test device ME includes a control unit TCON, a storage unit TMEM, a voltage measurement unit VMr, a voltage measurement unit VMp, a voltage measurement unit VMt, and a voltage output unit VFt. The control unit TCON is, for example, a CPU. The control unit TCON generates test patterns according to the test program stored in the storage unit TMEM and controls the voltage measurement unit VMr, the voltage measurement unit VMp, the voltage measurement unit VMt and the voltage output unit VFt to execute the test. The voltage measurement unit VMr is coupled to the terminal Tr of the semiconductor device 1 and measures the voltage of the terminal Tr. The voltage measurement unit VMp is coupled to the terminal Tp of the semiconductor device 1 and measures the voltage of the terminal Tp. The voltage measurement unit VMt is coupled to the terminal Tt of the semiconductor device 1 and measures the voltage of the terminal Tr. The voltage output unit VFt is coupled to the terminal Tt of the semiconductor device 1 and applies voltage to the terminal Tt. Additionally, the control unit TCON outputs a test mode signal TMODE to set the test mode of the semiconductor device 1. The control unit CON provided in the semiconductor device 1 controls on/off state of switch As within the temperature sensor THS based on the instructions of the test mode signal TMODE. Note that in FIG. 5, the test device ME is shown as a single device, but the test device ME, the control unit TCON, and voltage measurement units may be configured by coupling independent devices to each other.

The terminals Tr, Tp, and Tt are positioned closer to the temperature sensor THS1 in relative terms compared to the temperature sensor THSu (e.g., temperature sensors THS2, THS3, and THS4). In other words, the distance from the terminals Tr, Tp, and Tt to the temperature sensor THS1 is smaller than the distance from the terminals Tr, Tp, and Tt to any of the temperature sensors THS2, THS3, and THS4.

Voltage drop occurs when current flows through the terminals Tr, Tp, Tt, and Tvcc. The voltage drop amounts for the terminals Tr, Tp, Tt, and Tvcc are referred to as voltage drop Zr, voltage drop Zp, voltage drop Zt, and voltage drop Zvcc, respectively. The voltage drop Zt includes the load of the wiring to the pad or bump of terminal Tt and the load of the pad or bump. The load of the pad or bump includes the following (a) and (b). Note that voltage drop Zr, voltage drop Zp, and voltage drop Zvcc also include the load of the wiring to the pad or bump and the load of the pad or bump, although the load amounts differ.
(a) During wafer testing of the semiconductor device 1, the contact load with the probe
(b) During package testing of the semiconductor device 1, the contact load with the socket and the wiring load within the package

The voltage drop Zvcc of the terminal Tvcc has a large value, especially because the number of pads or bumps is large. The Voltage drop Zia and voltage drop Zib are voltage drops caused by each signal line La and Lb. The Voltage drop Zvcc is a voltage drop caused by wiring Lvcc. The voltage drop amount slightly changes depending on the voltage value applied to the wiring. Note that the unit of voltage drop is volts.

The signals handled in input and output are direct current (DC) voltage. The input of the voltage measurement unit of the semiconductor device 1, such as SoC, MCU, or chiplet, and the test device ME is high impedance. The wiring of the route indicated by the dotted line inside the temperature sensor THS1 shown in FIG. 5 is a short distance. Therefore, the impact of voltage drop is considered to be minimal. Additionally, the route from the terminals Tr, Tp, and Tt of the semiconductor device 1 to the test device ME, i.e., the wiring of the route indicated by the one-dot chain line in FIG. 5, is composed of wiring on the tester board, and the impact of voltage drop is considered to be minimal.

Next, a description will be given of the test for the temperature sensor within the semiconductor device 1. semiconductor device 1 executes the first to third tests described below for temperature characteristic correction of the temperature sensor.

### First Test

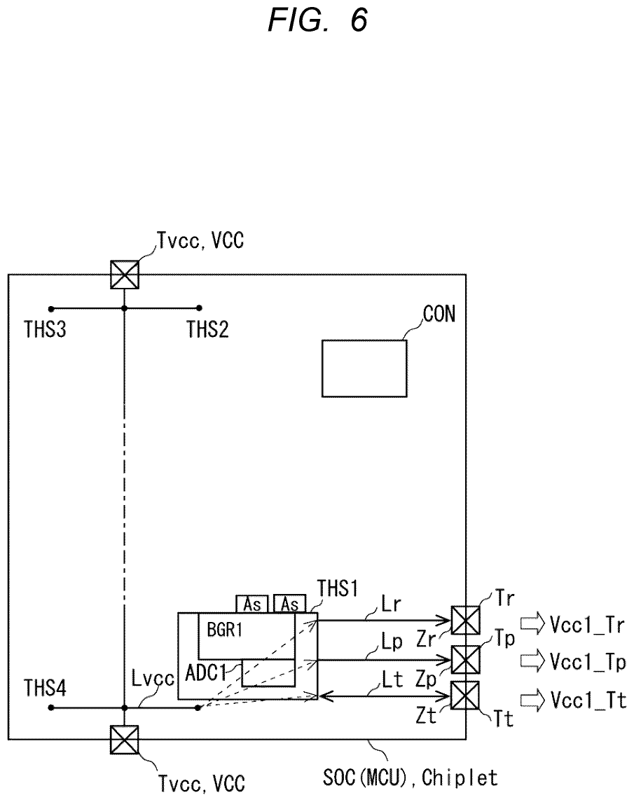

The first test is a test to understand measurement errors caused by probes, etc. The first test is executed according to the test program installed in the test device ME. The test device ME applies voltage to the semiconductor device 1, which is the device under test, according to the test program and outputs a test mode signal TMODE to execute the first test. FIG. 6 is a schematic diagram for explaining the first test of the semiconductor device 1 according to the first embodiment.

The semiconductor device 1 may further include wiring Lr, wiring Lp, wiring Lt, and wiring Lvcc. The wiring Lr couples the temperature sensor THS1 and the terminal Tr. The wiring Lp couples the temperature sensor THS1 and the terminal Tp. The wiring Lt couples the temperature sensor THS1 and the terminal Tt. The wiring Lvcc couples the temperature sensor THS1 and the terminal Tvcc. The wiring Lvcc connects to the wiring Lr, the wiring Lp, and the wiring Lt via switch As within the temperature sensor THS1.

The control unit CON of the semiconductor device 1 controls the operation of switch As in the semiconductor device 1 based on the instructions of the test mode signal TMODE output from the test device ME according to the test program. When the first test of the semiconductor device 1 starts, the control unit CON controls switch As within the temperature sensor THS1 so that the voltage appearing at the terminals Tr, Tp, and Tt is measured by the test device ME. Measurement errors caused by the probes can be obtained based on the measured voltages.

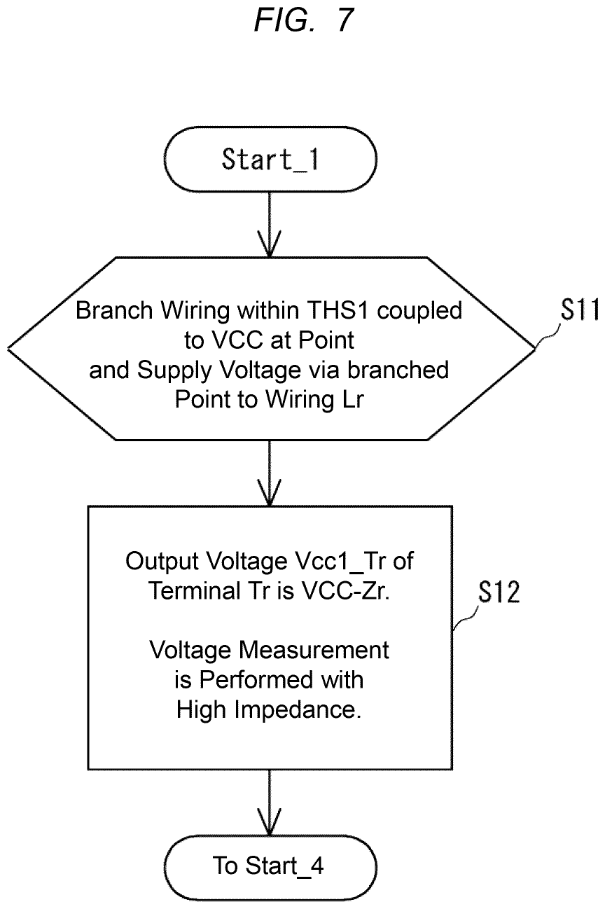

FIGS. 7 to 9 are flowcharts illustrating the operation of the first test in the semiconductor device 1 according to the first embodiment. As shown in FIG. 7, the control unit CON controls switch As within the temperature sensor THS1 so that the voltage VCC input from the terminal Tvcc can be measured at the terminal Tt.

Specifically, in step S11 (first measurement step), the control unit CON controls the switch As within the temperature sensor THS1 to branch a wiring within the temperature sensor THS1 which is coupled to the terminal Tvcc supplied with the voltage VCC at a point, and to supply a voltage via the point to the wiring Lr. In step S12, the voltage Vcc1_Tr (first measurement voltage) including the voltage drop Zr due to the terminal Tr and the wiring Lr, etc., is output from the terminal Tr. The output voltage Vcc1_Tr of the terminal Tr is VCC-Zr. The voltage measurement is performed with high impedance.

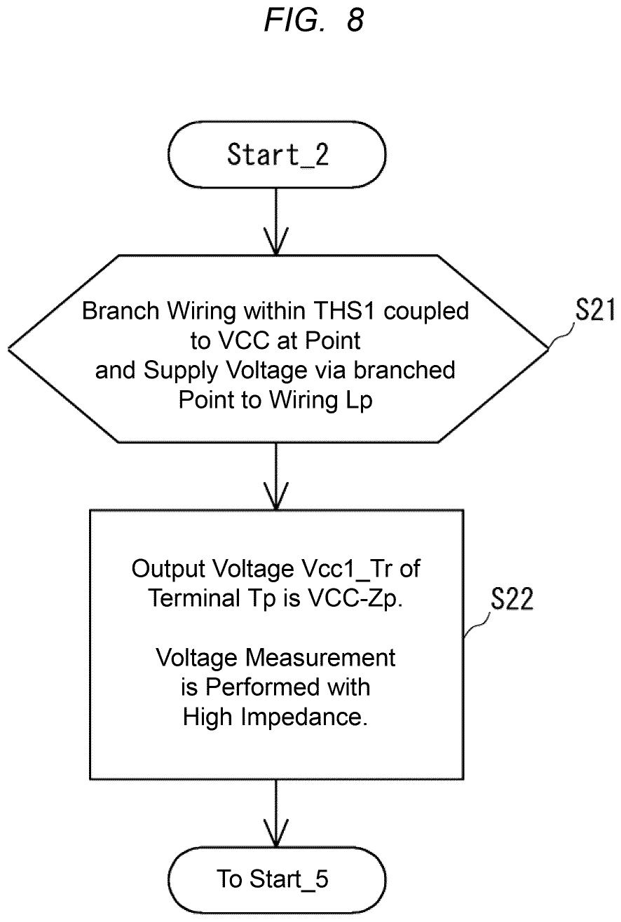

Next, as shown in FIG. 8, the control unit CON controls switch As within the temperature sensor THS1 so that the voltage VCC input from terminal Tvcc can be measured at terminal Tp. The voltage drop Zp may include the voltage drop of the wiring Lp.

Specifically, in step S21 (second measurement step), the control unit CON controls the switch As within the temperature sensor THS1 to branch the wiring within the temperature sensor THS1 which is coupled to the terminal Tvcc supplied with the voltage VCC at the aforementioned point within the temperature sensor THS1, and to supply the voltage via the point to the wiring Lp. In step S22, the voltage Vcc1_Tp (second measurement voltage) including the voltage drop Zp due to the terminal Tp and the wiring Lp, etc., is output from the terminal Tp. The output voltage Vcc1_Tp of the terminal Tp is VCC-Zp. The voltage measurement is performed with high impedance.

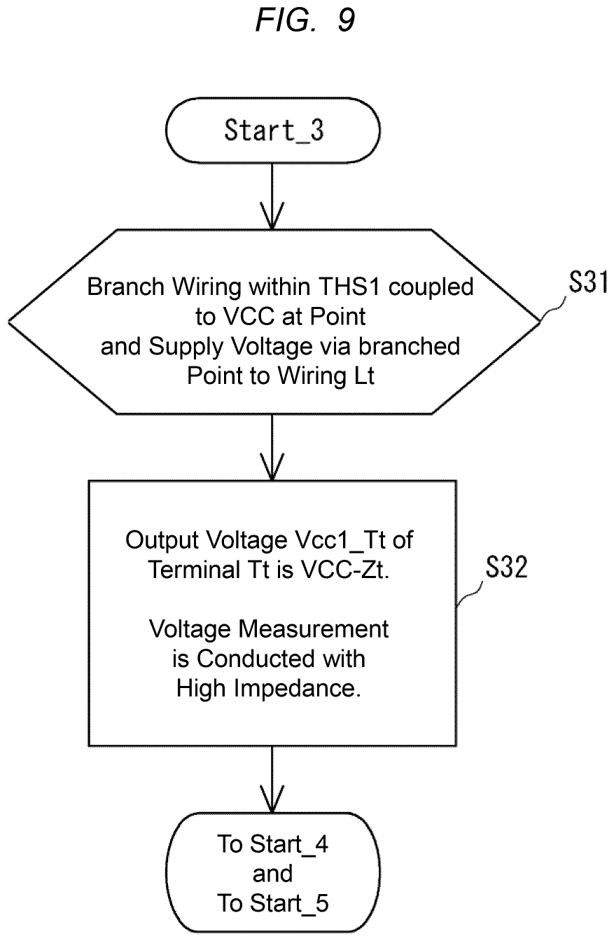

Furthermore, as shown in FIG. 9, the control unit CON controls switch As within the temperature sensor THS1 so that the voltage VCC input from terminal Tvcc can be measured at the terminal Tt. The Voltage drop Zt may include the voltage drop of the wiring Lt.

Specifically, in step S31, the control unit CON controls the switch As within the temperature sensor THS1 to branch the wiring which is coupled to the terminal Tvcc supplied with the voltage VCC at the aforementioned point within the temperature sensor THS1, and to supply the voltage via the point to the wiring Lt. In step S32, the voltage Vcc1_Tt, which includes the voltage drop Zt due to the terminal Tt and the wiring Lt, is output from the terminal Tt. The output voltage Vcc1_Tt of the terminal Tt is VCC-Zt. The voltage measurement is conducted with high impedance.

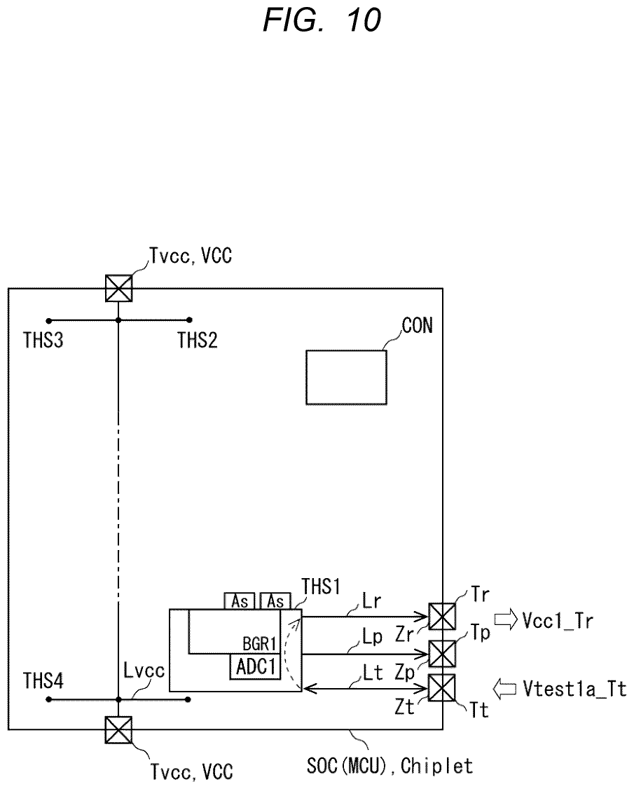

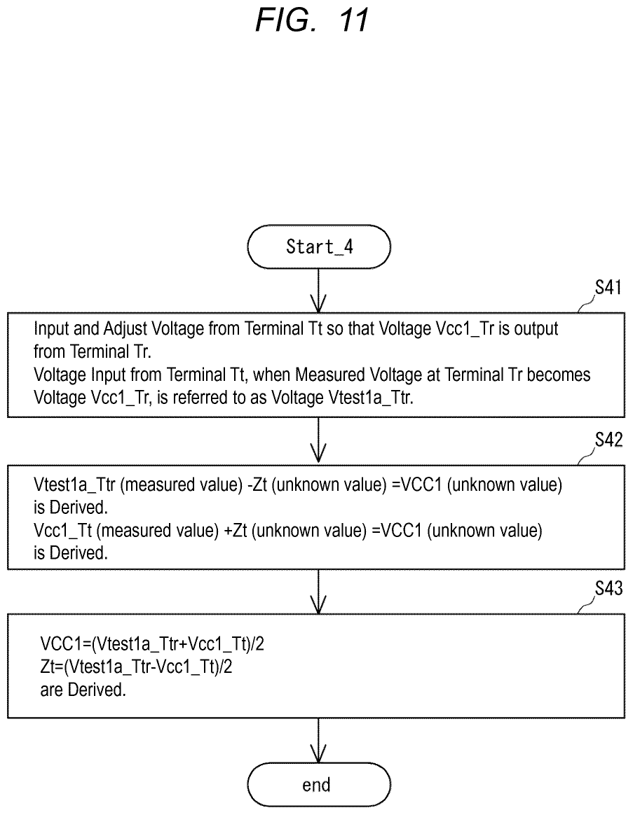

FIG. 10 is a schematic diagram for explaining the test operation following the test operation shown in FIG. 6 regarding the first test of the semiconductor device 1 according to the first embodiment. FIG. 11 is a flowchart illustrating the test operation following FIGS. 7 to 9 of the semiconductor device 1 according to the first embodiment. The control unit CON controls the switch As within the temperature sensor THS1 to form a route from the terminal Tt to the terminal Tr via the wiring Lt and the wiring Lr. This allows the voltage applied to the terminal Tt to be measured at the terminal Tr. Then, as shown in step S41 (third measurement step) of FIG. 11, the test device ME inputs voltage to the terminal Tt. The test device ME adjusts the voltage input to the terminal Tt so that the voltage Vcc1_Tr is output from the terminal Tr. The voltage input from terminal Tt when the measured voltage at terminal Tr becomes the voltage Vcc1_Tr is referred to as voltage Vtest1a_Ttr (third measurement voltage). The voltage drop Zt may include the voltage drop of the wiring Lt and Lr.

As shown in step S42 of FIG. 11, the following equations (1-1) and (1-2) are derived. Equation (1-2) is derived by setting the voltage VCC in step S32 as voltage VCC1.

$$Vtest 1 a\_Ttr - Z t = VCC 1 \qquad ( 1 - 1 )$$

$$Vcc 1 \_Tt + Z t = VCC 1 \qquad ( 1 - 2 )$$

Here, Vtest1a_Ttr and Vcc1_Tt are measured values, and VCC1 and Zt are unknown values. Therefore, in step S43, VCC1 and Zt are derived as shown in the following equations (1-3) and (1-4).

$$VCC 1 = ( Vtest 1 a\_Ttr + Vcc 1 \_Tt ) / 2 \qquad ( 1 - 3 )$$

$$Zt = ( Vtest 1 a\_Ttr - Vcc 1 \_Tt ) / 2 \qquad ( 1 - 4 )$$

In this way, the internal voltage VCC1 and voltage drop Zt of the temperature sensor THS1 are derived. The output voltage Vcc1_Tr of the terminal Tr is VCC1−Zr. Therefore, by using the value calculated in equation (1-3), the voltage drop Zr is obtained.

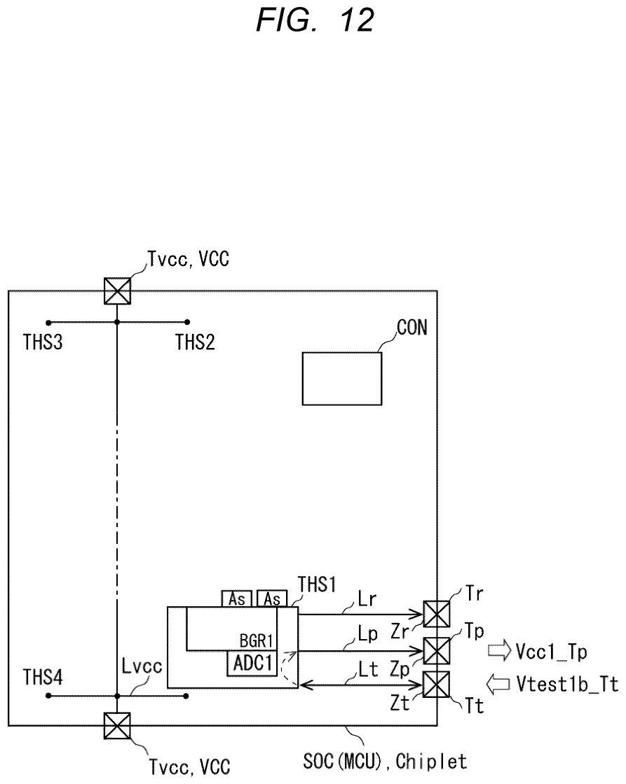

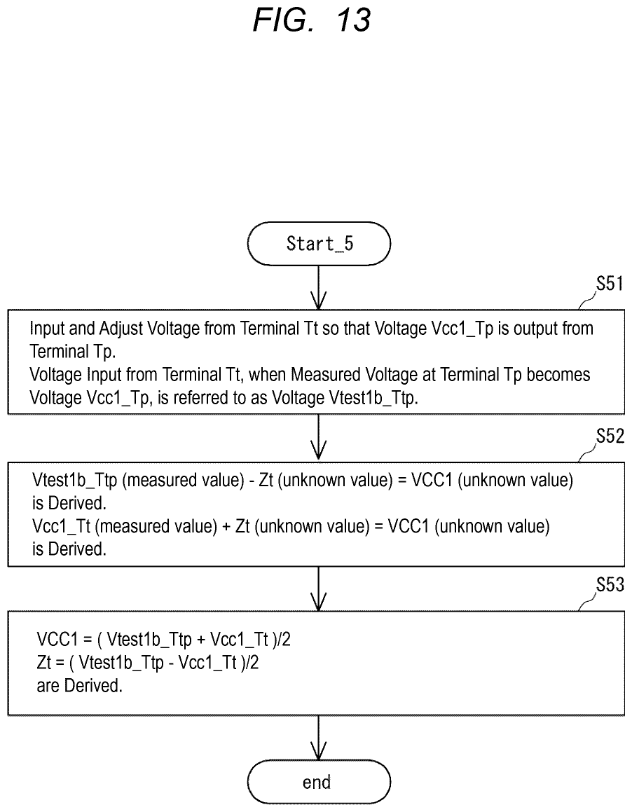

FIG. 12 is a schematic diagram for explaining the test operation following the test operation shown in FIG. 10 regarding the first test of the semiconductor device 1 according to the first embodiment. FIG. 13 is a flowchart illustrating the test operation following FIG. 11 of the semiconductor device 1 according to the first embodiment. The control unit CON controls the switch As within the temperature sensor THS1 to form a route from the terminal Tt to the terminal Tp via the wiring Lt and the wiring Lp. This allows the voltage applied to the terminal Tt to be measured at the terminal Tp. As shown in step S51 of FIG. 13, the test device ME inputs voltage from the terminal Tt. The test device ME adjusts the voltage input from terminal Tt so that t the voltage Vcc1_Tp is output from the terminal Tp. The voltage input from the terminal Tt when the measured voltage at the terminal Tp becomes voltage Vcc1_Tp is referred to as voltage Vtest1b_Ttp (fourth measurement voltage). The voltage drop Zt may include the voltage drop of the wirings Lt and Lr.

As shown in step S52 of FIG. 13, the following equations (2-1) and (2-2) are derived. Equation (2-2) is derived by setting the voltage VCC in step S32 of FIG. 9 as voltage VCC1.

$$Vtest 1 b\_ Ttp - Z t = VCC 1 \qquad ( 2 - 1 )$$

$$Vcc 1 \_Tt + Zt = VCC 1 \qquad ( 2 - 2 )$$

Here, Vtest1b_Ttp and Vc1_Tt are measured values, and VCC1 and Zt are unknown values. Therefore, in step S53, VCC1 and Zt are derived as shown in the following equations (2-3) and (2-4).

$$VCC 1 = ( Vtest 1 b\_Ttp + Vcc 1 \_Tt ) / 2 \qquad ( 2 - 3 )$$

$$Zt = ( Vtest 1 b\_Ttp - Vcc 1 \_Tt ) / 2 \qquad ( 2 - 4 )$$

In this way, the internal voltage VCC1 and voltage drop Zt of the temperature sensor THS1 are derived. The output voltage Vcc1_Tp of terminal Tp is VCC1-Zp. Therefore, by using the value calculated in equation (2-3), the voltage drop Zp is obtained.

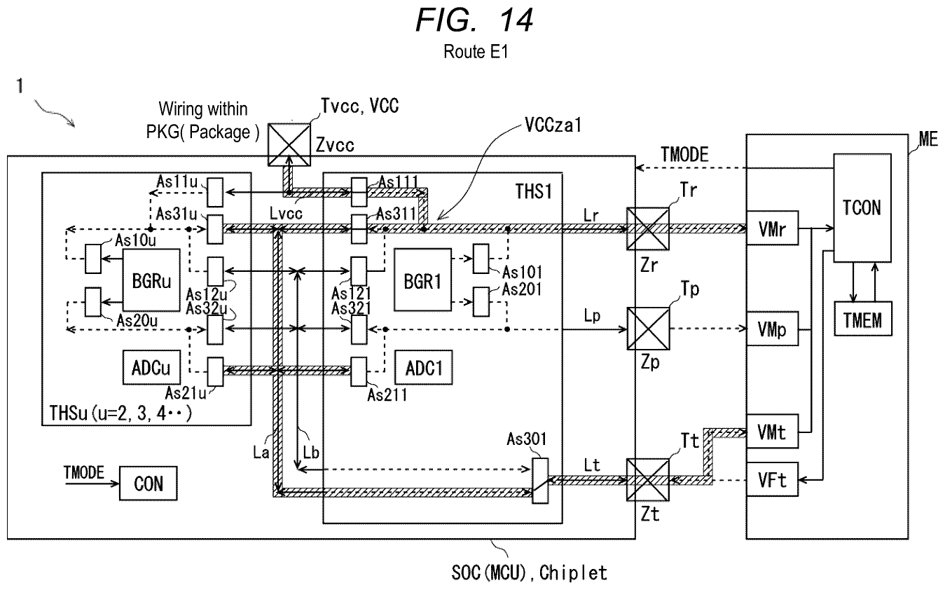

In the aforementioned first test, the route formed by the switch As within the temperature sensor THS1 is shown and explained in detail using FIGS. 14 to 17. To form these routes, the test device ME outputs the test mode signal TMODE according to the test program. Then, the control unit CON controls the switch As within the temperature sensor THS1 based on the instructions of the test mode signal TMODE.

FIG. 14 is a configuration diagram illustrating the semiconductor device 1 according to the first embodiment, showing the route related to the test operation shown in FIGS. 7 and 9. The route shown in FIG. 14 is referred to as route E1. As shown in FIG. 14, the voltage at a predetermined point of the temperature sensor THS1 is referred to as voltage VCCza1. The predetermined point is, for example, the point between the switch As111 and the switch As311 shown in the figure and the external terminal Tr. The voltage VCCza1 includes the voltage drop Zvcc1 due to the terminal Tvcc and the wiring Lvcc. The voltage at a predetermined position of the temperature sensor THSu (u=2, 3, 4 . . . ) is referred to as voltage VCCzau. The voltage VCCzau includes the voltage drop Zvccu due to the terminal Tvcc and the wiring Lvcc.

As shown in FIG. 14, in route E1, the voltage VCC is input to the temperature sensor THS1. The voltage VCC input to the temperature sensor THS1 is measured by the voltage measurement unit VMr via the terminal Tr. Additionally, the voltage VCC input to the temperature sensor THS1 is measured by the voltage measurement unit VMt via the signal line La and the terminal Tt. To form this route E1, the control unit CON turns on the switch As111 and the switch As311 based on the test mode signal TMODE from the test device ME. The control unit CON also controls the switch As301 so that the signal line La and the terminal Tt are coupled. In other words, route E1 is formed by the control of the third switch unit (the switches As301, As311, As121, As321, and As211) and the fourth switch unit (the switch As111) by the control unit CON.

The voltage is measured at the terminals of the voltage measurement unit VMr and the voltage measurement unit VMt on the test device ME side. The voltage measured at the terminal Tr by the voltage measurement unit VMr is referred to as Vmr_E1, and the voltage measured at the terminal Tt by the voltage measurement unit VMt is referred to as VMt_Ea1m. This leads to the following equations.

$$VCC = VCCza 1 + Zvcc 1 \qquad ( eqa 01 )$$

$$VMr\_E 1 = VCCza 1 - Zr \qquad ( eqa 02 )$$

$$VMt\_Ea 1 m = VCCza 1 - Zia - Zt \qquad ( eqa 03 )$$

From these equations, the following equation is derived.

$$VMr\_E 1 - VMt\_Ea 1 m = Zt + Zia - Zr \qquad ( eqa 04 )$$

$$Zr = Zt + Z i a - VMr\_E 1 + VMt\_Ea 1 m$$

VMr_E1 and VMt_Ea1m are values measured by the test device ME. VCCza1, Zr, Zt, and Zia are unknown values.

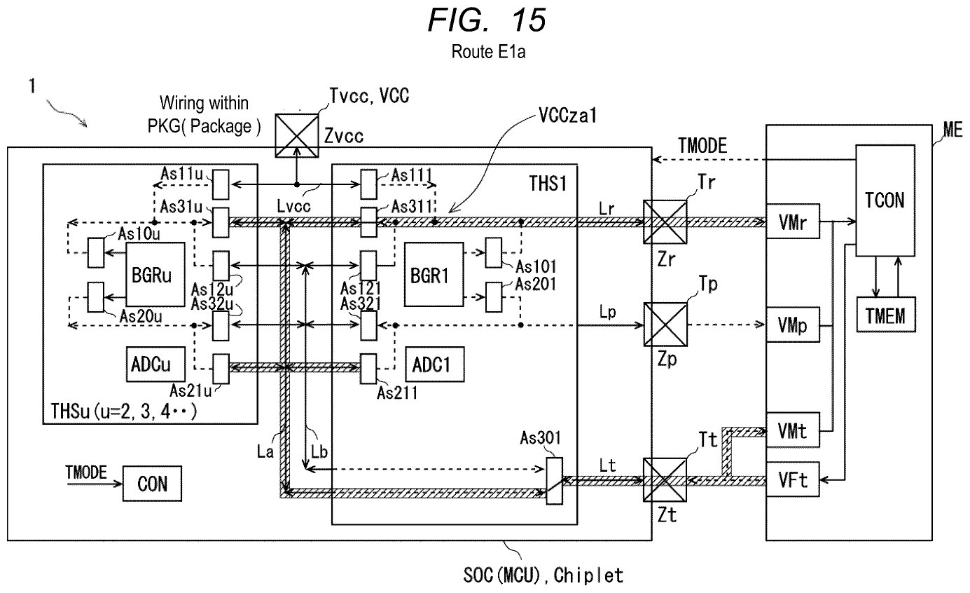

Subsequently, the control unit CON forms the route shown in FIG. 15 and executes the test. FIG. 15 is a configuration diagram illustrating the semiconductor device 1 according to the first embodiment, showing the route related to the test operation shown in FIG. 11. The route shown in FIG. 15 is referred to as route E1a. As shown in FIG. 15, in route E1a, the voltage input from the voltage output unit VFt via the terminal Tt is measured by the voltage measurement unit VMr via the signal line La, the temperature sensor THS1, and the terminal Tr. To form this route E1a, the control unit CON turns on the switch As311 based on the test mode signal TMODE from the test device ME. The control unit CON also controls the switch As301 so that the signal line La and the terminal Tt are coupled. In other words, the route E1a is formed by the control of the third switch unit (switch As301, As311, As121, As321, As211) by the control unit CON.

A voltage is input from the voltage output unit VFt on the test device ME side. The voltage output by the voltage output unit VFt when the voltage measured by the voltage measurement unit VMr becomes voltage VMr_E1 is referred to as voltage VFt_Ea1. Then, the following equation is obtained.

$$VMr\_E 1 = VFt\_Ea 1 - Zt - Zia - Zr \qquad ( eqa 05 )$$

$$VFt\_E1 - VMr\_E 1 = Z t + Z i a + Zr \qquad ( eqa 06 )$$

$$Zr = - Zt - Zia + VFt\_Ea 1 - VMr\_E 1$$

VMr_E1 is a measured value. VFt_Ea1 is a set value. Zr, Zt, and Zia are unknown values.

Here, the following equation is obtained from (eqa06)-(eqa04).

$$Z r = ( VFt\_Ea 1 - VMr\_E 1 - VMr\_E 1 + VMt\_Ea 1 m ) / 2 \qquad ( eqa 07 )$$

The calculated value VFt_Ea1 uses VMt_Ealf. This value is referred to as Zra. By rearranging (eqa02) and (eqa03), the following equations are obtained.

$$VCCza 1 = VMr\_E 1 - Zr \qquad ( eqa 08 )$$

$$VCCza 1 = VMt\_Ea 1 m + Zia + Zt$$

$$Zia + Z t = V CCzal 1 - VMt\_Ea 1 m \qquad ( eqa 09 )$$

VCCza1 and Zia+Zt are obtained as calculated values. Additionally, the following (Eeqa10) is obtained.

$$Z i a + Z t = VMt\_Ea 1 f - VCCza 1 \qquad ( eqa 10 )$$

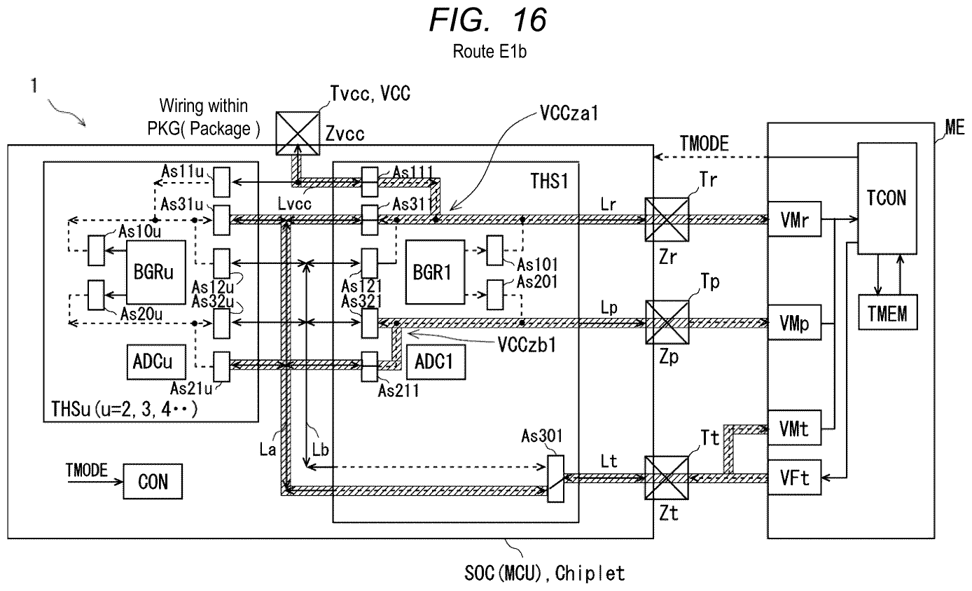

Subsequently, the control unit CON forms the route shown in FIG. 16 to conduct the test. FIG. 16 is a configuration diagram illustrating the semiconductor device 1 according to the first embodiment, showing the route related to the test operations depicted in FIGS. 7 to 9. The route shown in FIG. 16 is referred to as route E1b. As shown in FIG. 16, in route E1b, the voltage at a predetermined first point of the temperature sensor THS1 is set as voltage VCCza1. The voltage VCCza1 includes the voltage drop Zvcc1 due to terminal Tvcc and wiring Lvcc. The predetermined first point is, for example, the position between the switch As111, the switch As311, and the terminal Tr as shown in the figure. The predetermined first point is similar to the predetermined point of route E1.

Additionally, the voltage at a predetermined second point of the temperature sensor THS1 is set as voltage VCCzb1. The voltage VCCzb1 includes the voltage drop Zvcc1 due to terminal Tvcc and wiring Lvcc. The predetermined second point is, for example, the point between the switch As321, the switch As211, and the terminal Tp as shown in the figure.

The voltage VCC is input to the temperature sensor THS1. The voltage VCC input to the temperature sensor THS1 is measured by the voltage measurement unit VMr via the terminal Tr. Additionally, the voltage VCC input to the temperature sensor THS1 is measured by the voltage measurement unit VMt via the signal line La and the terminal Tt. Furthermore, the voltage VCC input to the temperature sensor THS1 is measured by the voltage measurement unit VMp via the signal line La and the terminal Tp. To form this route E1b, the control unit CON turns on the switch As111, the switch As311, and the switch As211 based on the test mode signal TMODE from the test device ME. Furthermore, the control unit CON controls the switch As301 so that the signal line La and the terminal Tt are coupled. In other words, the route E1b is formed by the control of the third switch unit (switches As301, As311, As121, As321, As211) and the fourth switch unit (switch As111) by the control unit CON.

As shown in FIG. 16, there is no difference between the voltage and current path from the predetermined point indicating the voltage VCCza1 as shown and the voltage and current path from the predetermined first point shown in route E1b. Therefore, the voltage is measured at the terminal of the voltage measurement unit VMr in route E1b. Then, it is compared with the voltage measured at the terminal of the voltage measurement unit VMr in route E1.

Additionally, in route E1b, the voltage is measured at the terminal of the voltage measurement unit VMp via the predetermined second point. Since the signal lines La and Lb viewed from the first point indicating voltage VCCza1 and the second point indicating voltage VCCzb1 are closely arranged, the voltage drops Zia and Zib are considered to be the same value. Thus, the following equations are derived.

$$VCC = VCCza 1 + Zvcc 1 \qquad ( eqa 01 )$$

$$VCCca 1 = VCCzb 1 + Zia \qquad ( eqa 11 )$$

$$VMr\_E 1 = V C Cza 1 - Zr \qquad ( eqa 02 )$$

$$VMp\_E 1 = V C Czb 1 - Zp \qquad ( eqa 12 )$$

$$VMt\_Ea 1 m = VCCza 1 - Zia - Zt \qquad ( eqa 03 )$$

$$VMt\_Ea 1 mp = VCCza 1 - Zia - Zt \qquad ( eqa 13 )$$

$$VMr\_E 1 - VMt\_Ea 1 m = Zt + Z i a - Zr \qquad ( eqa 04 )$$

$$VMr\_E 1 - VMt\_Ea 1 mp = Z t + Z i a - Z r \qquad ( eqa 14 )$$

Then, from (eqa13) and (eqa14), the following equations are derived.

$$VMt\_Ea 1 m = VMt\_Ea 1 mp \qquad ( eqa 16 )$$

$$VMt\_Ea 1 mp = V C Czb 1 - Zia - Zt \qquad ( eqa 17 )$$

$$VMp\_E 1 - VMt\_Ea 1 mp = Zt + Zia - Zp \qquad ( eqa 18 )$$

VMr_E1 and VMt_Ea1mp are values measured by the test device ME. Zr and VCCza1 are obtained based on (eqa07) and (eqa08), respectively. Zp, Zt, and Zia are unknown values. However, Zt+Zia is a value that can be obtained based on (eqa09).

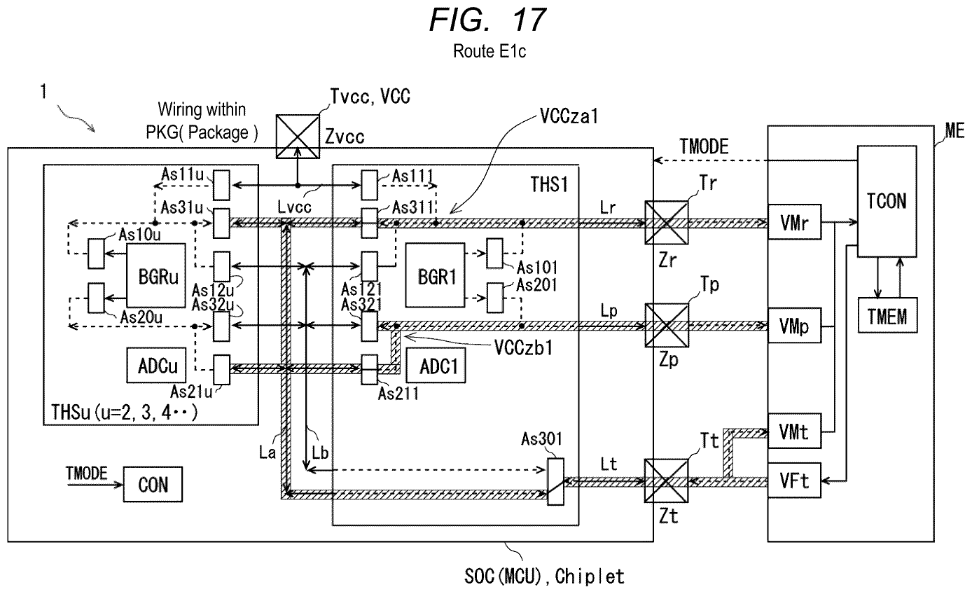

FIG. 17 is a configuration diagram illustrating the semiconductor device 1 according to the first embodiment, showing the route related to the test operations depicted in FIG. 13. The route shown in FIG. 17 is referred to as route E1c. As shown in FIG. 17, in route E1c, the voltage input from the voltage output unit VFt via the terminal Tt is measured by the voltage measurement unit VMr via the signal line La, the temperature sensor THS1, and the terminal Tr. Additionally, the voltage input from the voltage output unit VFt via the terminal Tt is measured by the voltage measurement unit VMp via the signal line La, the temperature sensor THS1, and the terminal Tp. To form this route E1c, the control unit CON turns on the switches As311 and As211 based on the test mode signal TMODE from the test device ME. Additionally, the control unit CON controls the switch As301 so that the signal line La and the terminal Tt are coupled. In other words, the route E1c is formed by the control of the third switch unit (switches As301, As311, As121, As321, As211) and the fourth switch unit (switch As111) by the control unit CON.

The voltage is input from the voltage output unit VFt of the test device ME. The voltage output by the voltage output unit VFt when the voltage measured by the voltage measurement unit VMr becomes voltage VMr_E1, and when the voltage measured by the voltage measurement unit VMp becomes voltage VMp_E1, is referred to as voltage VFt_Ea1p. Thus, the following equations are obtained.

$$VMr\_E 1 = VFt\_Ea 1 - Zt - Zia - Zr \qquad ( eqa 05 )$$

$$VMp\_E 1 = VFt\_Ea 1 p - Zt - Zia - Zp \qquad ( eqa 19 )$$

$$VFt\_Ea 1 - VMr\_E 1 = Z t + Z i a + Zr \qquad ( eqa 06 )$$

$$VFt\_Ea 1 p - VMp\_E 1 = Z t + Z i a + Zp \qquad ( eqa 20 )$$

VMr_E1 and VMp_E1 are measured values. VFt_Ea1p is a set value. Zr is a known value. Zp, Zt, and Zia are unknown values.

Here, from (eqa20)-(eqa18), the following equation is obtained.

$$Zp = ( VFt\_Ea1 p - VMp\_E 1 - VMp\_E 1 + VMt\_Ea 1 mp ) / 2 \qquad ( eqa 21 )$$

VFt_Ea1p uses VMt_Ea1fp. This value is referred to as Zpα. By rearranging (eqa17) and (eqa18), the following equations are obtained.

$$VCCzb 1 = VMp\_E1 - Zp \qquad ( eqa22 )$$

$$Zia + Zt = VCCzb 1 - VMt\_Ea1fp \qquad ( eqa23 )$$

Therefore, Zia+Zt is obtained by calculation.

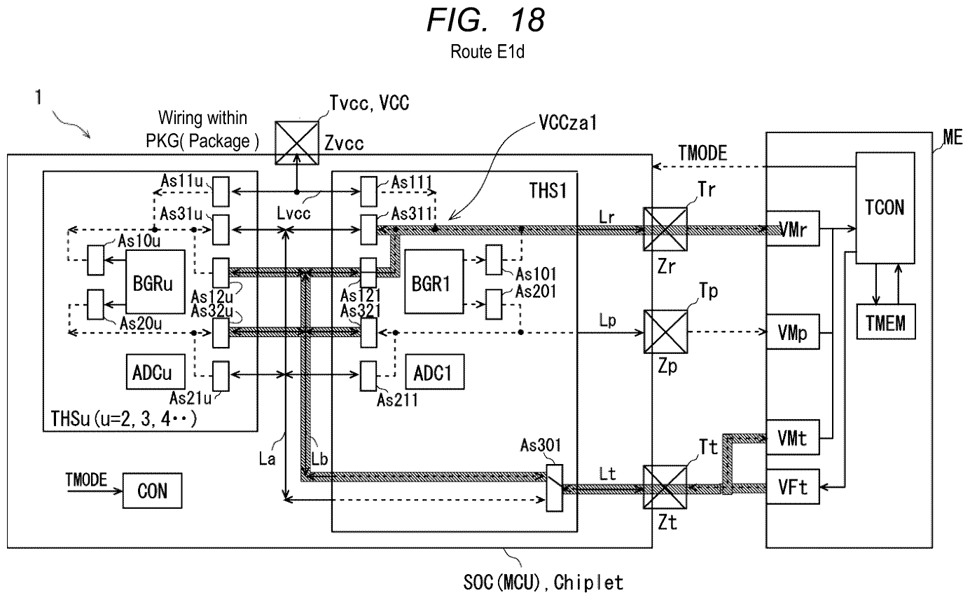

Subsequently, the control unit CON forms the route shown in FIG. 18 to execute the test. FIG. 18 is a configuration diagram illustrating the semiconductor device 1 according to the first embodiment, showing the route related to the test operations depicted in FIG. 11. The route shown in FIG. 18 is referred to as route Eld. As shown in FIG. 18, in route Eld, the voltage input from the voltage output unit VFt via the terminal Tt is measured by the voltage measurement unit VMr via the signal line Lb, the temperature sensor THS1, and the terminal Tr. To form this route Eld, the control unit CON turns on the switch As121 based on the test mode signal TMODE from the test device ME. Additionally, the control unit CON controls the switch As301 so that the signal line Lb and the terminal Tt are coupled. The following provides a specific explanation. The route Eld is formed by the control of the third switch unit (switches As301, As311, As121, As321, As211) by the control unit CON.

The voltage is input from the voltage output unit VFt of the test device ME. The voltage output by the voltage output unit VFt when the voltage measured by the voltage measurement unit VMr becomes voltage VMr_E1 is referred to as voltage VFt_Eb1. Thus, the following equations are obtained.

$$VMr\_E 1 = VFt\_Eb1 - Zt - Zib - Zr \qquad ( eqa31 )$$

$$Zt + Zib = VFt\_Eb1 - VMr\_E 1 - Zr$$

$$Zt + Zib = VMt\_Eb1f - VMr\_E 1 - Zr \qquad ( eqa32 )$$

Zt+Zib is obtained as a calculated value. VMr_E1 is a measured value. VFt_Eb1 is a set value. Zr, Zt, and Zib are unknown values. Zib+Zt is obtained from the above (eqa09).

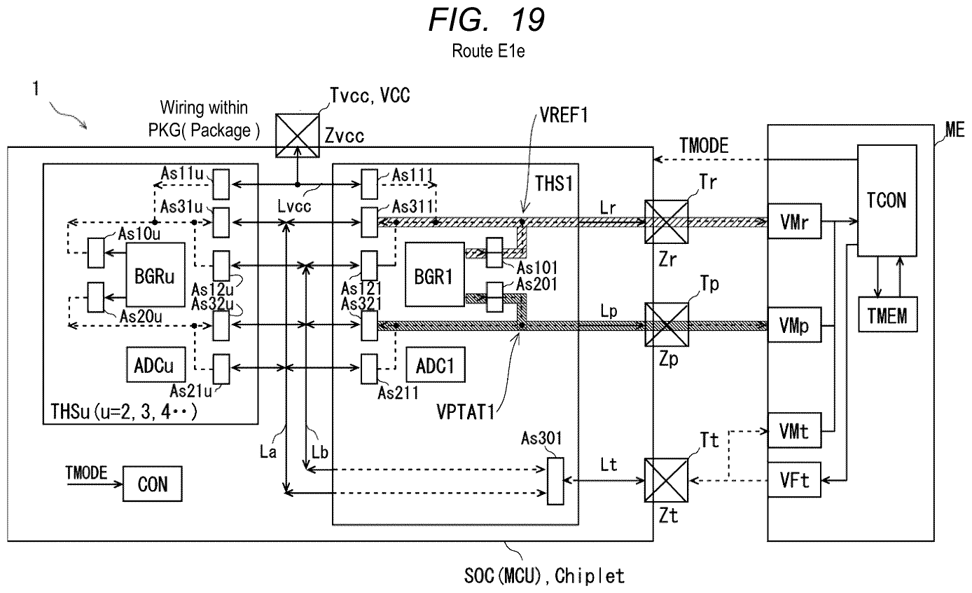

After forming the routes from FIGS. 14 to 18 and obtaining the values of each voltage drop, the reference voltage VREF1 and the PTAT voltage VPTAT1 output by the bandgap reference circuit BGR1 of the temperature sensor THS1 are measured. FIG. 19 is a configuration diagram illustrating the semiconductor device 1 according to the first embodiment, showing the route for measuring the reference voltage VREF1 and the PTAT voltage VPTAT1 output by the bandgap reference circuit BGR1 of the temperature sensor THS1 at the terminals Tr and Tp. The route shown in FIG. 19 is referred to as route Ele. As shown in FIG. 19, in route Ele, the voltage VREF1 of the reference voltage Vref1 output from the bandgap reference circuit BGR1 of the temperature sensor THS1 is measured by the voltage measurement unit VMr via the terminal Tr. Also, in route Ele, the voltage VPTAT1 of the PTAT voltage ptat1 output from the bandgap reference circuit BGR1 of the temperature sensor THS1 is measured by the voltage measurement unit VMp via the terminal Tp. To form this route Ele, the control unit CON turns on the switch As101 and the switch As201 based on the test mode signal TMODE from the test device ME. The route Ele is formed by the control of the first switch unit (switch As101) and the second switch unit (switch As201) by the control unit CON. Here, if the voltages measured by the voltage measurement units VMr and VMp are denoted as voltage VMr_VREF1 and voltage VMp_VPTAT, respectively, the following equations are obtained.

$$VREF 1 = VMr\_VREF1 + Zr α \qquad ( eqa41 )$$

$$VPTAT 1 = VMr\_VPTAT1 + Zp α \qquad ( eqa42 )$$

The voltage drops Zrα and Zpα are values calculated by the aforementioned test operation. Therefore, by correcting the measured voltages VMr_VREF1 and VMp_VPTAT1 with the voltage drops Zrα and Zpα, the voltages VREF and VPTAT of the temperature sensor THS1 can be obtained accurately. Although not shown in the figure, the AD conversion value of VPTAT1/VREF1 is also obtained.

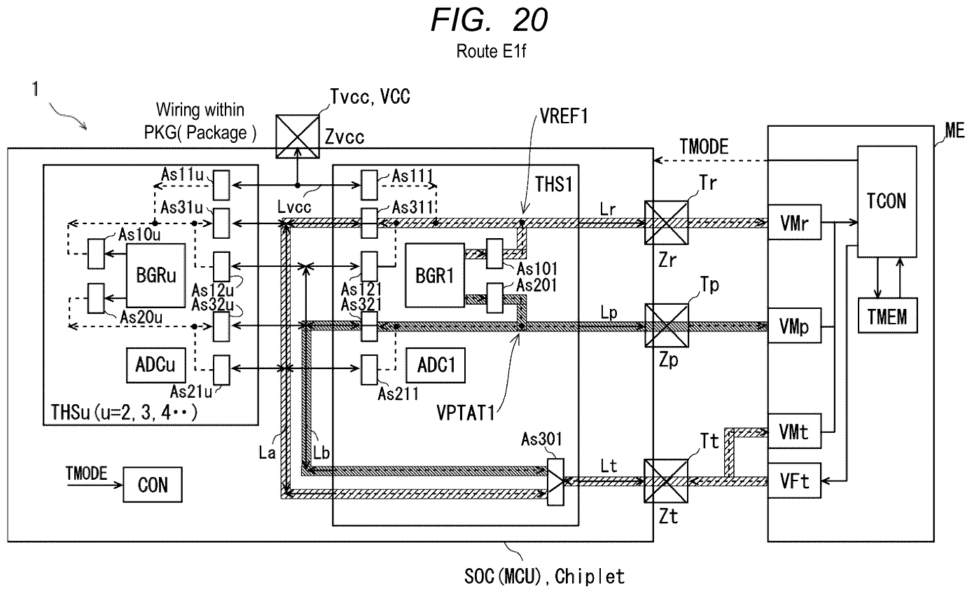

FIG. 20 is a configuration diagram illustrating the semiconductor device 1 according to the first embodiment, showing the case of route Elf. As shown in FIG. 20, in route Elf, the voltage VREF1 of the reference voltage Vref1 output from the bandgap reference circuit BGR1 of the temperature sensor THS1 is measured by the voltage measurement unit VMt via the signal line La and the terminal Tt.

$$VREF 1 = VMr\_VREF1 + Zr α \qquad ( eqa43 )$$

$$VREF 1 = VMt\_VREF 1 + ( Zia + Zt ) \qquad ( eqa44 )$$

$$VPTAT 1 = VMr\_VPTAT1 + Zp α \qquad ( eqa45 )$$

Although not shown in the figure, the AD conversion value of VPTAT1/VREF1 is also obtained.

Also, in route Elf, the voltage VPTAT1 of the PTAT voltage ptat1 output from the bandgap reference circuit BGR1 of the temperature sensor THS1 is measured by the voltage measurement unit VMt via the signal line Lb and the terminal Tt. Therefore, the following equations are obtained.

$$VREF 1 = VMr\_VREF1 + Zr α \qquad ( eqa46 )$$

$$VPTAT 1 = VMr\_VPTAT1 + Zp α \qquad ( eqa47 )$$

$$VPTAT 1 = VMt\_VPTAT1 + ( Zib + Zt ) \qquad ( eqa48 )$$

Although not shown in the figure, the AD conversion value of VPTAT1/VREF1 is also obtained.

From the starting point of the reference voltage Vref1 and PTAT voltage ptat1 from the bandgap reference circuit BGR1 on the circuit, the following equations are confirmed.

$$( eqa 41 ) = ( eqa 43 ) = ( eqa 44 ) = ( eqa 46 )$$

$$( eqa 42 ) = ( eqa 45 ) = ( eqa 47 ) = ( eqa 48 )$$

In this way, the terminal Tr outputs the first reference voltage Vref1. The terminal Tp outputs the first detection voltage (first PTAT voltage Vptat1). The first switch unit (switch As101) is provided to output the first reference voltage Vref1 from the terminal Tr. The second switch unit (switch As201) is provided to output the first detection voltage (first PTAT voltage Vptat1) from the terminal Tp. The third switch unit (switches As301, As311, As121, As321, As211) is provided between the terminal Tt and the terminals Tr and Tp, and the fourth switch unit (As111) is provided between the point where the power supply voltage is supplied and the terminal Tr.

The test method related to the first test of the semiconductor device 1 includes the first measurement step, second measurement step, third measurement step, fourth measurement step, and calculation step as described above. Here, the first measurement step includes controlling the third and fourth switch units so that the power supply voltage is output from the terminal Tr, and obtaining the first measurement voltage from the terminal Tr. The second measurement step includes controlling the third and fourth switch units so that the power supply voltage is output from the terminal Tp, and obtaining the second measurement voltage from the terminal Tp. The third measurement step includes controlling the third switch unit to output the voltage supplied from the terminal Tt at terminal Tr, and measuring the third measurement voltage where the first measurement voltage is obtained at the terminal Tr. The fourth measurement step includes controlling the third switch unit to output the voltage supplied from the terminal Tt at terminal Tp, and measuring the fourth measurement voltage where the second measurement voltage is obtained at the terminal Tp. The calculation step includes calculating the measurement error of terminal Tr based on the first and third measurement voltages and calculating the measurement error of terminal Tp based on the second and fourth measurement voltages.

### Second Test

The second test is a test to understand the impact of voltage drop based on the internal wiring from temperature sensor THS1 to temperature sensor THSu. The second test is performed following the first test. The second test is performed according to the test program installed in the test device ME. As shown in FIG. 5, the semiconductor device 1 in the first embodiment has two bidirectional signal lines La and Lb as signal lines between each temperature sensor THS. Additionally, the two signal lines La and Lb are configured to allow loopback by the switch As within the temperature sensor THS. For example, the reference voltage Vref1 is supplied from the temperature sensor THS1 to the temperature sensor THS3 via the signal line La. The reference voltage Vref1 supplied to the temperature sensor THS3 is returned to the temperature sensor THS1 via the signal line Lb. This allows the voltage difference between the supply voltage and the return voltage to be obtained at the terminals Tr and Tp coupled to the temperature sensor THS1. Additionally, the voltage difference between the supply voltage and the return voltage can be AD converted by the ADC of the temperature sensor THS1. Using this difference (voltage fluctuation), the impact of voltage drop based on the internal wiring from the temperature sensor THS1 to the temperature sensor THSu can be estimated.

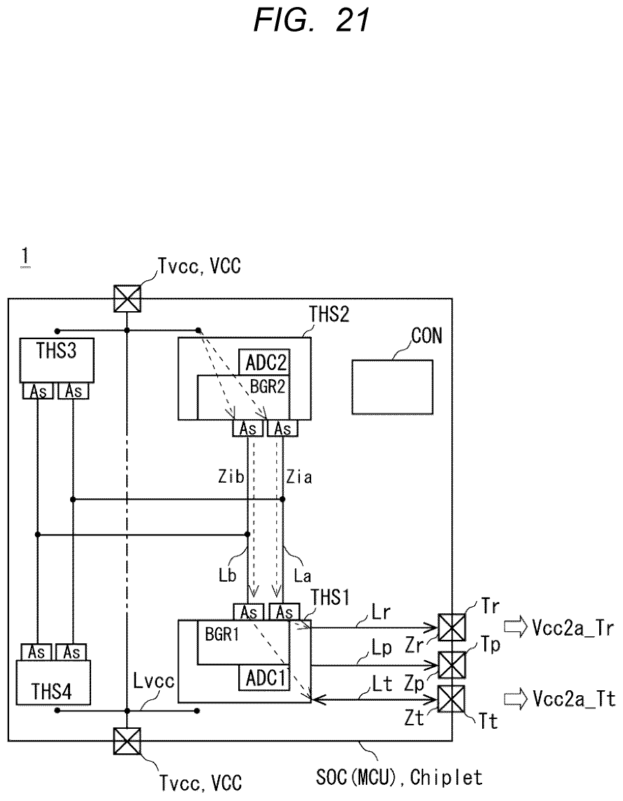

FIG. 21 is a schematic diagram for explaining the second test of the semiconductor device 1 according to the first embodiment. As shown in FIG. 21, the semiconductor device 1 includes the temperature sensor THS2 and the signal lines La and Lb. Here, the temperature sensor THS2 is used as an example to explain a temperature sensor THSu. The temperature sensor THS2 includes a bandgap reference circuit BGR2 and a plurality of switches As. The signal line La couples the temperature sensor THS1 and the temperature sensor THS2. The signal line Lb couples the temperature sensor THS1 and the temperature sensor THS2.

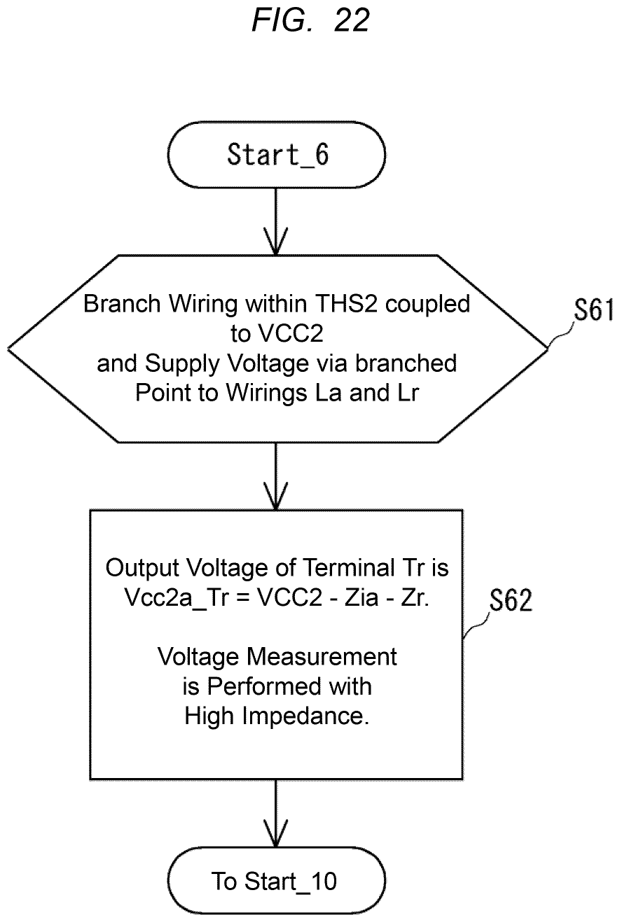

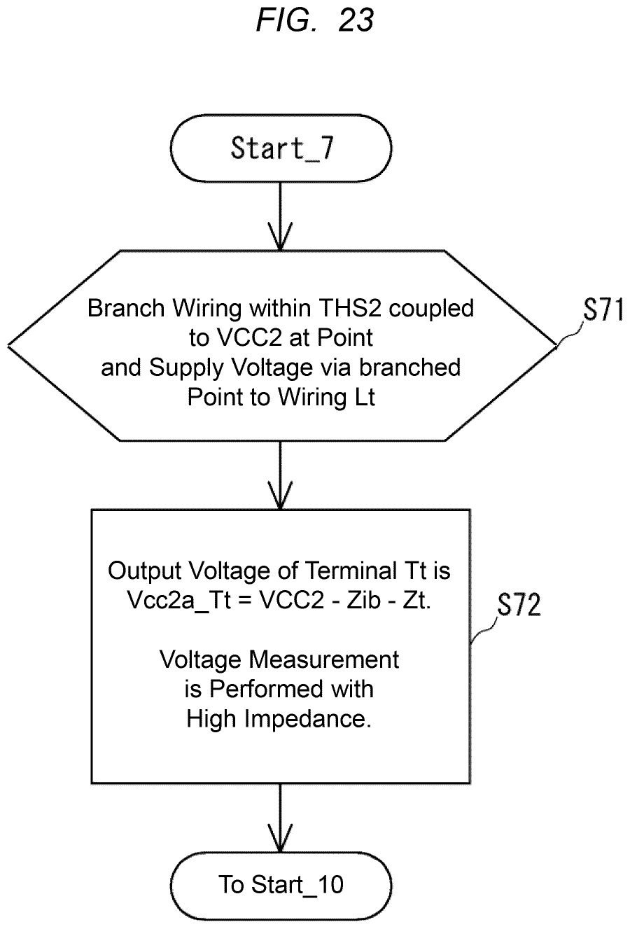

FIGS. 22 and 23 are flowcharts illustrating the test operation of the second test of the semiconductor device 1 according to the first embodiment.

As shown in FIG. 22, when the second test of the semiconductor device 1 is started, the control unit CON controls to output, from the terminal Tr, the voltage Vcc2a_Tr including the voltage drop (Zia+Zr) to the voltage VCC2 input from terminal Tvcc. The voltage drop (Zia+Zr) is caused by the signal line La and the terminal Tr. The voltage drop (Zia+Zr) may include the voltage drop of wiring Lr.

Specifically, in step S61 (fifth measurement step), the control unit CON controls to branch a wiring within the temperature sensor THS2 coupled to the terminal Tvcc supplied with the voltage VCC2 at a point and to supply a voltage via the point to the signal line La and the wiring Lr. As shown in step S62, the voltage Vcc2a_Tr, which includes the voltage drop (Zia+Zr) by the signal line La, the wiring Lr and the terminal Tr, is output from the terminal Tr. The output voltage Vcc2a_Tr of the terminal Tr is VCC2-Zia-Zr. The voltage measurement is performed with high impedance.

Next, as shown in FIG. 23, the control unit CON controls to output, from terminal Tt, the voltage Vcc2a_Tt including the voltage drop (Zib+Zt) to the voltage VCC2 input from terminal Tvcc. The voltage drop (Zib+Zt) is caused by the signal line Lb and the terminal Tt. The voltage drop (Zib+Zt) may include the voltage drop of wiring Lt.

Specifically, in step S71 (fifth measurement step), the control unit CON controls the switch As of the temperature sensor THS1 and the switch As of the temperature sensor THS2 to branch the wiring within temperature sensor THS2 which is coupled to the terminal Tvcc supplied with the voltage VCC2 at the above-mentioned point, and to supply the voltage to signal line Lb and wiring Lt. As shown in step S72, the control unit CON outputs the voltage Vcc2a_Tt, which includes the voltage drop (Zib+Zt) by signal line Lb, wiring Lt, and terminal Tt, from terminal Tt. The output voltage Vcc2a_Tt of terminal Tt is VCC2-Zib-Zt. The voltage measurement is performed with high impedance.

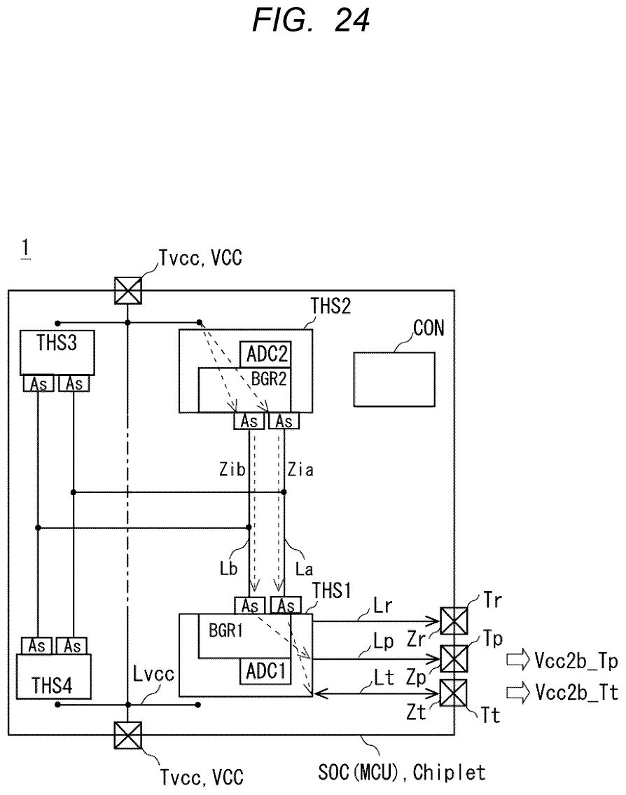

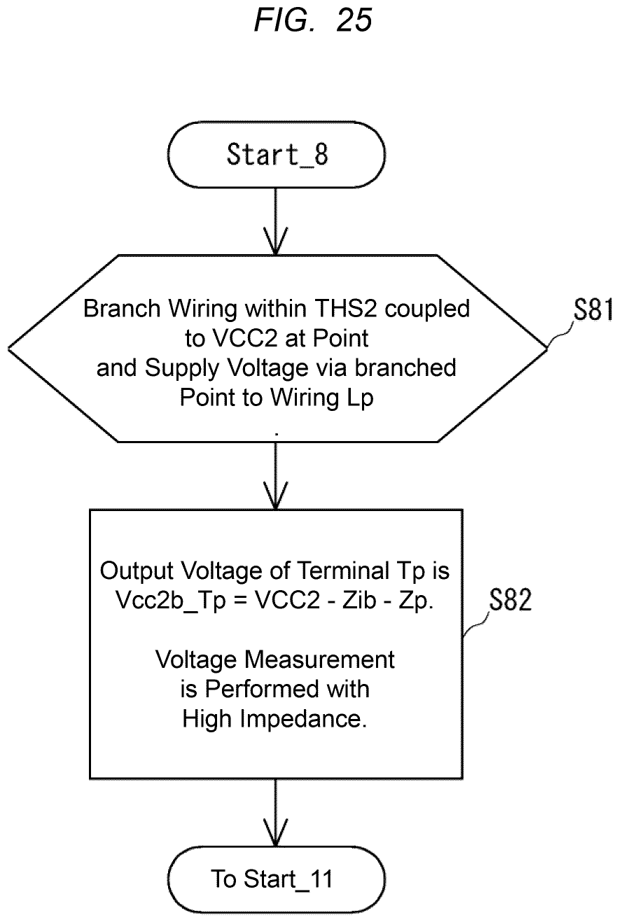

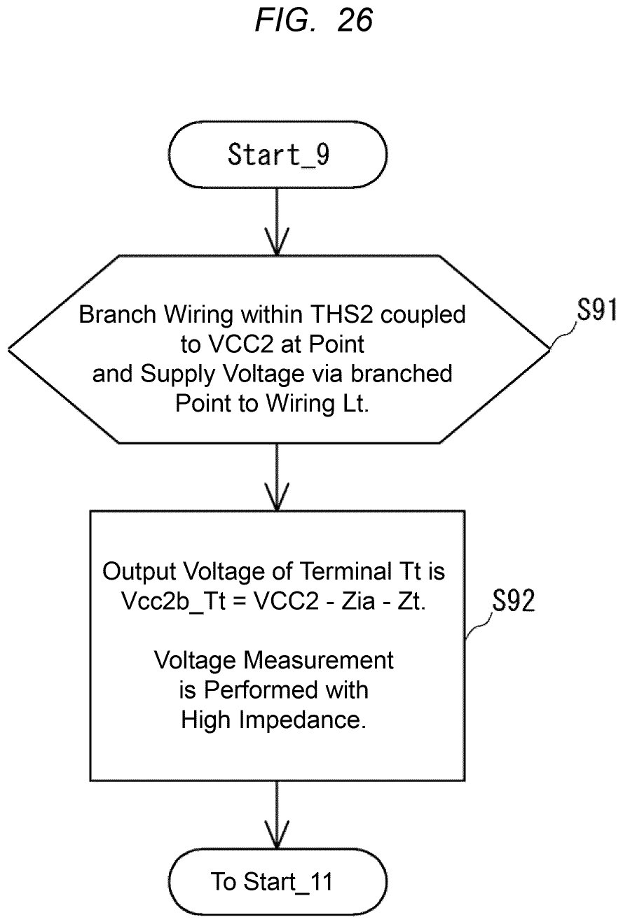

FIG. 24 is a schematic diagram for explaining the test operation following the test operation shown in FIG. 21 regarding the second test of the semiconductor device 1 according to the first embodiment. FIGS. 25 and 26 are flowcharts illustrating the test operation (sixth measurement step) following FIGS. 22 and 23 regarding the second test of the semiconductor device 1 according to the first embodiment. As shown in FIGS. 24 and 25, the control unit CON controls the switch As to output, from terminal Tp, the voltage Vcc2b_Tp including the voltage drop (Zib+Zp) to the voltage VCC2 supplied from the terminal Tvcc. The voltage drop (Zib+Zp) is caused by the signal line Lb and terminal Tp. The voltage drop (Zib+Zp) may include the voltage drop of the wiring Lp.

Specifically, in step S81, the control unit CON controls the switch As of temperature sensor THS2 and the switch As of temperature sensor THS1 to branch the wiring within temperature sensor THS2 coupled to the terminal Tvcc supplied with the voltage VCC2 at the specified point on the wiring, and to supply a voltage via the point to the signal line Lb and the wiring Lp. As shown in step S82, the control unit CON controls to output, from the terminal Tp, the voltage Vcc2b_Tp including the voltage drop (Zib+Zp) due to the signal line Lb, the wiring Lp, and the terminal Tp. The output voltage Vcc2b_Tp of the terminal Tp is VCC2-Zib-Zp. The voltage measurement is performed with high impedance.

Next, as shown in FIGS. 24 and 26, the control unit CON controls the switch As to output, from the terminal Tt, the voltage Vcc2b_Tt including the voltage drop (Zia+Zt) to the voltage VCC2 supplied from the terminal Tvcc. The voltage drop (Zia+Zt) is caused by the signal line La and the terminal Tt. The voltage drop (Zia+Zt) may include the voltage drop of the wiring Lt.

Specifically, in step S91, the control unit CON controls the switch As of temperature sensor THS2 and the switch As of THS1 to branch the wiring within temperature sensor THS2 coupled to the terminal Tvcc supplied with the voltage VCC2 at the specified point on the wiring, and to supply the voltage to the signal line La and the wiring Lt. In step S92, the control unit CON controls to output, from the terminal Tt, the voltage Vcc2b_Tt including the voltage drop (Zia+Zt), which is caused by the signal line La, the wiring Lt, and the terminal Tt. The output voltage Vcc2b_Tt of the terminal Tt is VCC2-Zia-Zt. The voltage measurement is performed with high impedance.

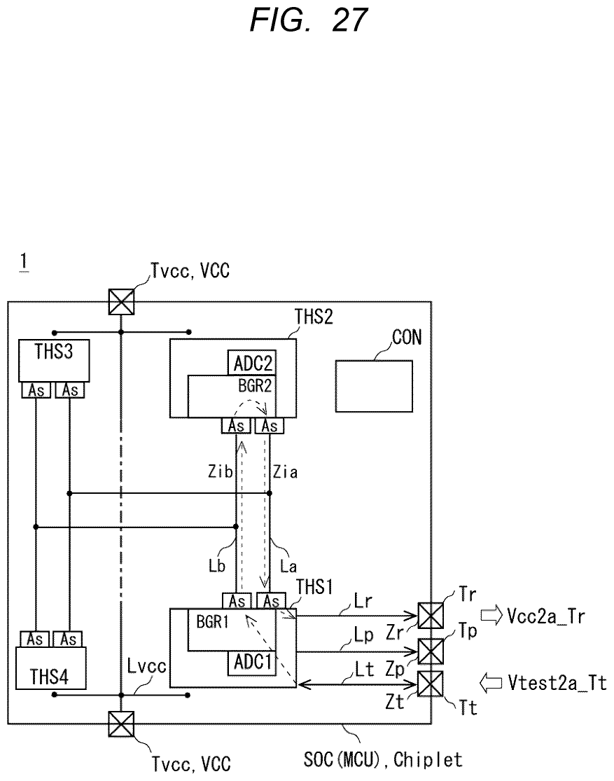

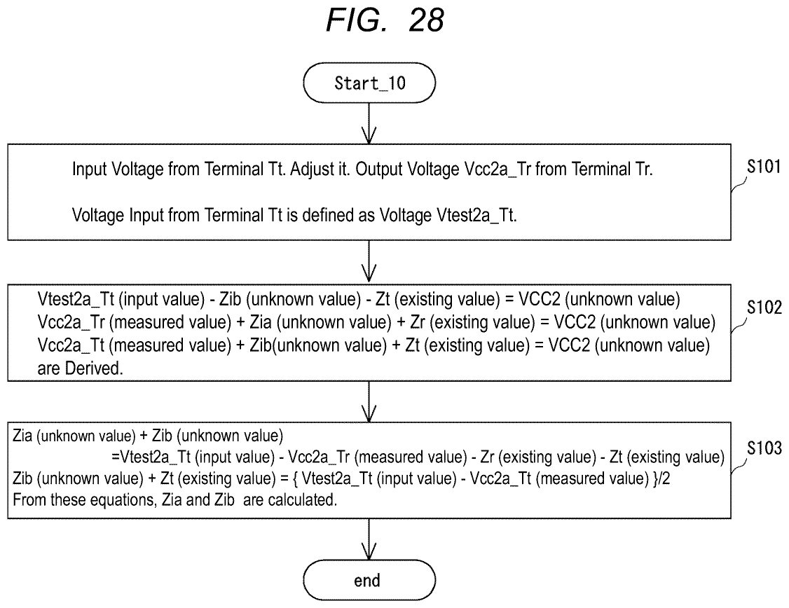

FIG. 27 is a schematic diagram for explaining the test operation following the test operation shown in FIG. 24 regarding the second test of the semiconductor device 1 according to the first embodiment. FIG. 28 is a flowchart illustrating the test operation (seventh measurement step) following FIGS. 25 and 26 regarding the second test of the semiconductor device 1 according to the first embodiment. As shown in FIGS. 27 and 28, in step S101, the test device ME inputs voltage from the terminal Tt. The test device ME adjusts the voltage input from the terminal Tt. The test device ME adjusts the input voltage to the terminal Tt to output the voltage Vcc2a_Tr from the terminal Tr. The voltage input from the terminal Tt when the measured voltage of the terminal Tr becomes the voltage Vcc2a_Tr is defined as voltage Vtest2a_Tt.

Thus, the control unit CON controls to output, from the terminal Tt, the voltage VCC2a_Tr including the voltage drop Zib and the voltage drop Zt to the test voltage Vtest2a_Tt supplied from the terminal Tt. The voltage drop Zib is caused by the signal line Lb and the voltage drop Zt is caused by the terminal Tt.

In step S102, the following equations (3-1) to (3-3) are derived. Equation (3-2) is derived from step S62, and equation (3-3) is derived from step S72.

$$Vtest2a\_Tt - Zib - Zt = VCC 2 \qquad ( 3 ‐ 1 )$$

$$Vcc2a\_Tr + Zia + Zr = VCC 2 \qquad ( 3 ‐ 2 )$$

$$Vcc2a\_Tt + Zib + Zt = VCC 2 \qquad ( 3 ‐ 3 )$$

Here, Vtest2a_Tt is the input value, Vcc2a_Tr and Vcc2a_Tt are the measured values, and VCC2, Zia, and Zib are unknown values. In step S103, the following equations (3-4) and (3-5) are derived from equations (3-1) to (3-3).

$$Zia + Zib = Vtest2a\_Tt - Vcc 2 a \_Tr - Zr - Zt \qquad ( 3 ‐ 4 )$$

$$Zib + Zt = ( Vtest2a\_Tt - Vcc2a\_Tt ) / 2 \qquad ( 3 ‐ 5 )$$

From equations (3-4) and (3-5), the voltage drop Zia of the signal line La and the voltage drop Zib of the signal line Lb are calculated.

The leak current occurring in the wiring route of the signal line La and the wiring route of the signal line Lb is explained. The wiring route of the signal line La and the wiring route of the signal line Lb are configured with high impedance. Therefore, the leak current occurs in elements such as the switch As. For example, the arrangement relationship of elements such as the switch As in the circuit has symmetry when applying voltage VCC2 to the terminal Tvcc and when applying voltage Vtest2a_Tt to the terminal Tt in semiconductor device 1. Thus, the difference in voltage drop distribution on the test path due to the difference in test methods when applying voltage VCC2 to the terminal Tvcc and when applying voltage Vtest2a_Tt to the terminal Tt can be ignored.

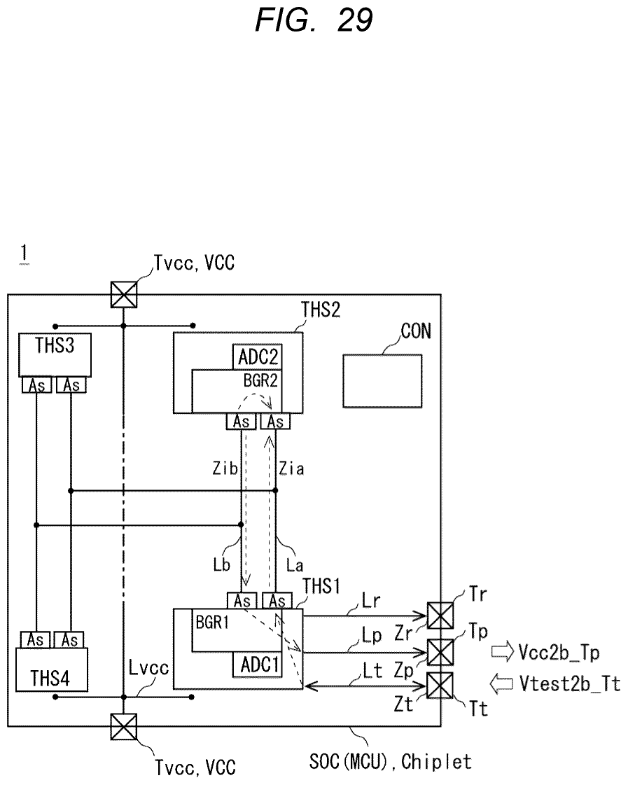

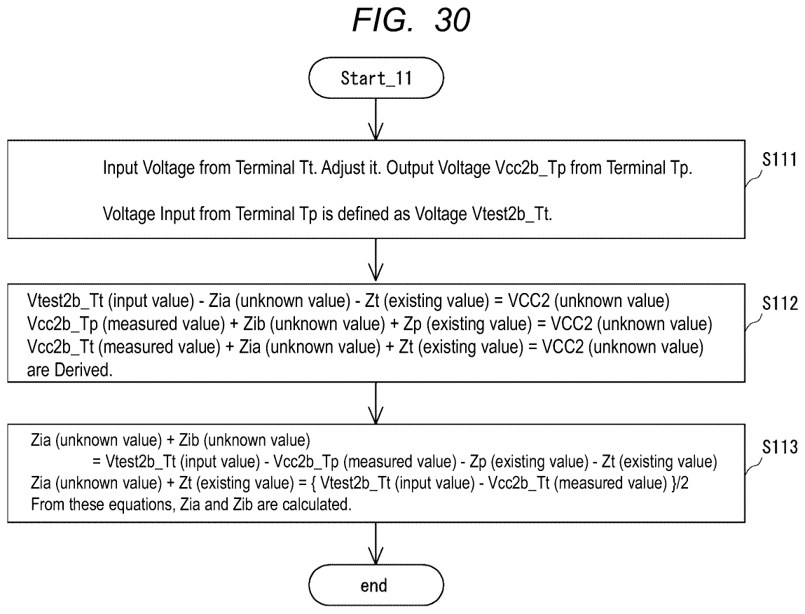

FIG. 29 is a schematic diagram for explaining the test operation following the test operation shown in FIG. 27 regarding the second test of the semiconductor device 1 according to the first embodiment. FIG. 30 is a flowchart illustrating the test operation (eighth measurement step) following FIG. 28 regarding the second test of the semiconductor device 1 according to the first embodiment. As shown in FIGS. 29 and 30, in step S111, the control unit CON controls the switch As of temperature sensor THS2 and the switch As of temperature sensor THS1, forming a route from the terminal Tt to the terminal Tp via the wiring Lt, the wiring La, and the wiring Lb. In this state, the test device ME inputs voltage from the terminal Tt. The test device ME adjusts the voltage input from the terminal Tt. The measuring device ME adjusts the input voltage to terminal Tt to output the voltage Vcc2b_Tp from terminal Tp. The voltage input from the terminal Tt when the measured voltage of the terminal Tp becomes voltage Vcc2b_Tp is defined as voltage Vtest2b_Tt.

Thus, the control unit CON controls to output, from the terminal Tp, the voltage VCC2b_Tp including the voltage drop Zia due to the signal line La and the voltage drop Zt due to the terminal Tt to the test voltage Vtest2b_Tt from terminal Tt.

In step S112, the following equations (4-1) to (4-3) are derived. Equation (4-2) is derived from step S82, and equation (4-3) is derived from step S92.

$$Vtest2b\_Tt - Zia - Zt = VCC 2 \qquad ( 4 ‐ 1 )$$

$$Vcc2b\_Tp + Zib + Zp = VCC 2 \qquad ( 4 ‐ 2 )$$

$$Vcc2b\_Tt + Zia + Zt = VCC 2 \qquad ( 4 ‐ 3 )$$

Here, Vtest2b Tt is the input value, VCC2b_Tp and VCC2b_Tt are the measured values, and VCC2, Zia, and Zib are unknown values. In step S113, the following equations (4-4) and (4-5) are derived from equations (4-1) to (4-3).

$$Zia + Zib = Vtest2b\_Tt - VCC2b\_Tp - Zp - Zt \qquad ( 4 ‐ 4 )$$

$$Zia + Zt = ( Vtest2b\_Tt - VCC2b\_Tt ) / 2 \qquad ( 4 ‐ 5 )$$

From equations (4-4) and (4-5), the voltage drop Zia of the signal line La and the voltage drop Zib of the signal line Lb are calculated.

Thus, the second test allows for the determination of the voltage drop Zia of the signal line La and the voltage drop Zib of the signal line Lb.

Thus, the semiconductor device 1 of this embodiment further includes the fifth to eighth switch units. The fifth switch unit (switch As10u) and the sixth switch unit (switch As20u) are coupled to the output of the temperature sensor THSu. The seventh switch unit (switches As30u, As31u, As12u, As32u, As21u) is coupled between the signal line La and the signal line Lb. The eighth switch unit (switch As11u) is coupled between the point where the power supply voltage is supplied to the temperature sensor THSu and the seventh switch unit.

The test method for such a semiconductor device 1 includes the following fifth measurement step, sixth measurement step, seventh measurement step, eighth measurement step, and second calculation step. Here, the fifth measurement step includes the control unit CON controlling the third, seventh, and eighth switch units by the control unit CON to measure the power supply voltage with the terminal Tr via the signal line La and to measure the power supply voltage with the terminal Tt via the signal line Lb. The sixth measurement step includes the control unit CON controlling the third, fourth, and eighth switch units to measure the power supply voltage with the terminal Tp via the signal line Lb and to measure the power supply voltage with the terminal Tt via the signal line La. The seventh measurement step includes the control unit CON controlling the third and seventh switch units to measure the voltage supplied to the terminal Tt with the terminal Tr via the signal line La and the signal line Lb in sequence. The eighth measurement step includes the control unit CON controlling the third and seventh switch units to measure the voltage supplied to terminal Tt with the terminal Tp via the signal line Lb and the signal line La in sequence. The second calculation step includes calculating the voltage drop of the signal line La and the signal line Lb based on the voltage measured in the fifth to eighth measurement steps.

In the semiconductor device 1 of the first embodiment, the signal lines La and Lb are provided, and by using the switch As provided within the temperature sensor to loop back, the voltage drop of the signal wiring to each temperature sensor THS is measured. The voltage difference between the supply voltage and the return voltage is measured using two different signal lines La and Lb. Since the voltage drop of these two signal lines La and Lb is not necessarily the same, the voltage drop cannot be obtained as a specific numerical value by loopback alone.

Therefore, in the second test, the voltage VCC supplied to each temperature sensor THS is input to two different signal lines La and Lb and output to the terminals Tr and Tp. The difference between the terminal Tr and the terminal Tp can be obtained as the difference in voltage drop between the two different signal lines La and Lb. Using the obtained difference and the voltage drop obtained by looping back the two different signal lines La and Lb, the individual voltage drops of signal lines La and Lb can be obtained.

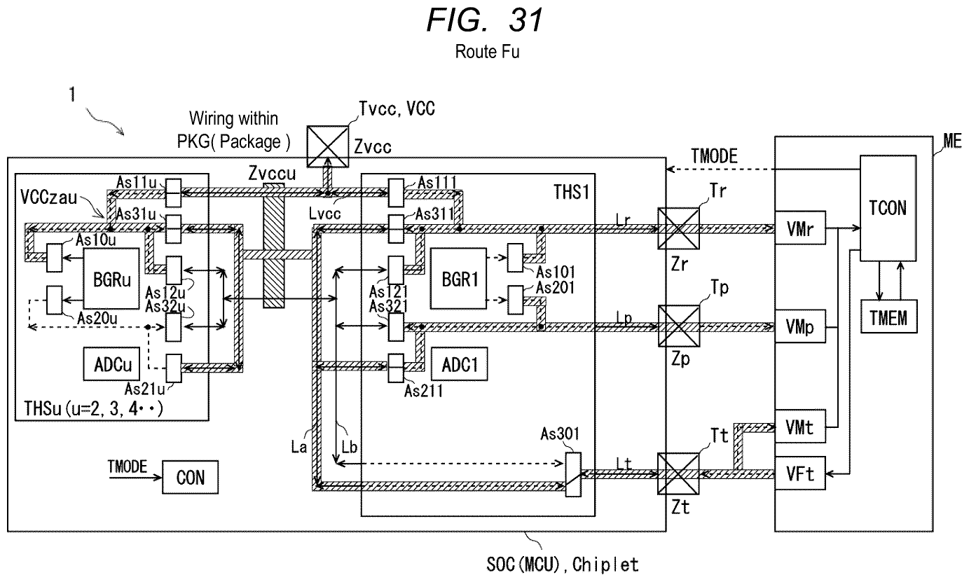

In the aforementioned second test, while showing the route formed by the switch As of each temperature sensor, the second test operation is explained in detail using FIGS. 31 to 33. In order to form these routes, the test device ME outputs the test mode signal TMODE according to the test program. Then, the control unit CON controls the switch As based on the instructions of the test mode signal TMODE.

The impact on the voltage drops Zia of the signal line La and the voltage drop Zib of the signal line Lb is considered. The voltage drops Zia and voltage drop Zib are the loads of the signal lines La and Lb where analog signals are transmitted near temperature sensor THS1, as well as the terminals Tr, Tp, and Tt. The total length of the signal lines La and Lb includes the portions coupled to the temperature sensors THS2 to THS4.

The signals of each temperature sensor THS and the signal lines La and Lb, are transmitted near the positions where each temperature sensor THS is located. The signals of signal lines La and Lb between the temperature sensors THS are transmitted the distance to the location of each temperature sensor THS.

FIG. 31 is a configuration diagram illustrating the semiconductor device 1 according to the first embodiment, showing the route related to the test operation shown in FIGS. 22 and 23. The route shown in FIG. 31 is referred to as route Fu. The control unit CON turns on the switch As311 and the switch As211 of the temperature sensor THS1, and the switch As11u and the switch As31u of the temperature sensor THSu to form route Fu. Furthermore, the control unit CON controls switch As301 so that signal line La and terminal Tt are connected. In other words, the route Fu is formed by the control of the third switch unit (switches As301, As311, As121, As321, As211), the seventh switch unit (switches As30u, As31u, As12u, As32u, As21u), and the eighth switch unit (switch As11u) by the control unit CON. In FIG. 31, the voltage drops Ziau and Zibu of the signal lines La and Lb due to the distance to the location of each temperature sensor THSu are shown as blocks of voltage drop Zvccu. The transmission of signals is mainly conducted between the terminals Tr, Tp, and Tt, which are located near the temperature sensor THS1, and the temperature sensor THS1. Therefore, here, the distance between the temperature sensor THS1 and the temperature sensor THSu (u=2, 3, 4 . . . ) is considered.

As shown in FIG. 31, the voltage at a predetermined position of temperature sensor THSu is referred to as voltage VCCzau. The predetermined position is, for example, the position between the switch As10u, the switch As11u, and the switch As31u of the temperature sensor THSu shown in the figure. Voltage VCCzau includes the voltage drop Zvccu. As shown in FIG. 31, in the route Fu, the voltage VCC is input to the temperature sensor THS1 and the temperature sensor THSu. The voltage VCC input to the temperature sensor THS1 and the temperature sensor THSu is measured by the voltage measurement unit VMr via the switch As11u, the switch As31u, the switch As311, and the terminal Tr.

Additionally, the voltage VCC input to the temperature sensor THS1 and the temperature sensor THSu is measured by the voltage measurement unit VMp via the signal line La and the terminal Tp. Furthermore, the voltage VCC input to the temperature sensor THS1 and the temperature sensor THSu is measured by the voltage measurement unit VMt via the switch As11u, the switch As31u, the signal line La, the switch As301, and the terminal Tt. Hereafter, a concrete description will be given. It should be noted that the temperature sensors THS2, THS3, and THS4, etc., cannot be measured simultaneously and are measured individually.

The voltages at the terminals Tr, Tp, and Tt are measured by the voltage measurement units VMr, VMp, and VMt of the test device ME. As a result, the following equations are derived.

$$VCC = VCCzau + Zvccu \qquad ( eqa51 )$$

$$VMr\_Fus = VCCzau - Ziau - Zr \qquad ( eqa52 )$$

$$VMp\_Fus = VCCzau - Ziau - Zp \qquad ( eqa53 )$$

$$VMt\_Fus = VCCzau - Ziau - Zt \qquad ( eqa54 )$$

$$VMr\_E1 - VMt\_Ea1m = Zt + Zia - Zr \qquad ( eqa 04 )$$

$$Zr = Zt + Zia - VMr\_E1 + VMt\_Ea1m$$

VMr_Fus, VMp_Fus, and VMt_Fus are measured values. Zr, Zp, and Zt are calculated by the aforementioned test. VCCzau and Zia are unknown values.

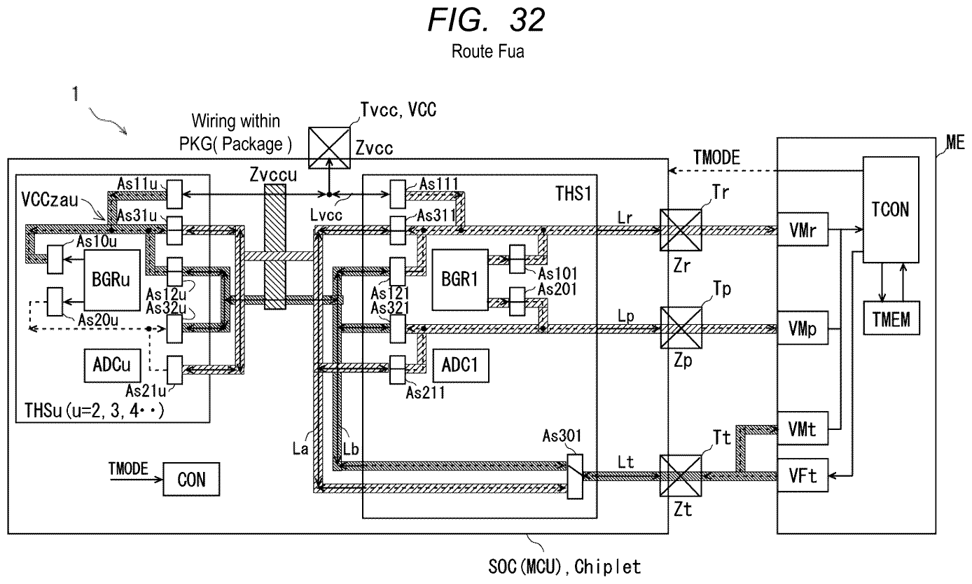

FIG. 32 is a configuration diagram illustrating the semiconductor device 1 according to the first embodiment, showing the route related to the test operation shown in FIGS. 28 and 30. The route shown in FIG. 32 is referred to as route Fua. As shown in FIG. 32, in route Fua, the voltage input from the voltage output unit VFt via the terminal Tt is measured by the voltage measurement unit VMr via the terminal Tr. Also, in route Fua, the voltage input from the voltage output unit VFt via the terminal Tt is measured by the voltage measurement unit VMp via terminal Tp. To form this route Fua, the control unit CON controls the switch As301 so that the signal line Lb and the terminal Tt are coupled. Additionally, the control unit CON turns on switch As12u, switch As31u, switch As311, and switch As211 in response to the test mode signal TMODE from the test device ME. In other words, route Fua is formed by the control of the third switch unit (switch As301, As311, As121, As321, As211) and the seventh switch unit (switches As30u, As31u, As12u, As32u, As21u) by the control unit CON.

A voltage is input from the voltage output unit VFt of the test device ME. The voltage output by the voltage output unit VFt when the voltage measured by the voltage measurement unit VMr becomes voltage VMr_Fus is referred to as voltage VFt_Fuf. In this case, the voltage of the voltage output unit VMt is referred to as voltage VMt_Fuf.

Also, a voltage output by the voltage output unit VFt when the voltage measured by the voltage measurement unit VMp becomes voltage VMp_Fus is referred to as voltage VFt_Fuf. In this case, the voltage of the voltage output unit VMt is referred to as voltage VMt_Fuf. Then, the following equation is obtained.

$$VMt\_Fuf = VCCzau - Zibu - Zt \qquad ( eqa55 )$$

From (eqa55)-(eqa54), the following equation is obtained.

$$VMt\_Fuf - VMt\_Fus = Ziau - Zibu \qquad ( eqa56 )$$

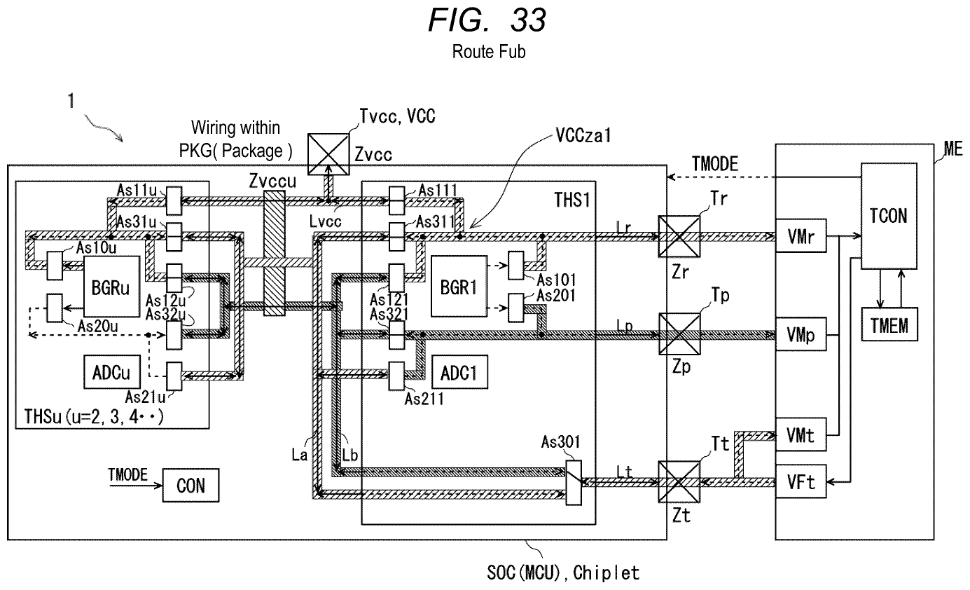

Subsequently, the control unit CON forms the route shown in FIG. 33 and conducts the test. FIG. 33 is a configuration diagram illustrating the semiconductor device 1 according to the first embodiment, showing the case of route Fub. As shown in FIG. 33, in route Fub, voltage VCCza1 is input to the temperature sensor THS1 and temperature sensor THSu. The voltage VCCza1 input to the temperature sensor THS1 and the temperature sensor THSu is measured by the voltage measurement unit VMr via the terminal Tr.

Additionally, the voltage VCCza1 input to the temperature sensor THS1 and the temperature sensor THSu is measured by the voltage measurement unit VMp via the signal line La and the terminal Tp. Furthermore, the voltage VCCza1 input to the temperature sensor THS1 and the temperature sensor THSu is measured by the voltage measurement unit VMt via the signal line La and the terminal Tt. To form this route Fub, the control unit CON turns on the switch As111, the switch As311, and the switch As31u based on the test mode signal TMODE from the test device ME. Additionally, the control unit CON controls the switch As301 so that the signal line Lb and the terminal Tt are coupled and turns on the switch As321. In other words, the route Fub is formed by the control of the third switch unit (switchs As301, As311, As121, As321, As211), the fourth switch unit (switch As111), and the seventh switch unit (switches As30u, As31u, As12u, As32u, As21u) by the control unit CON. Hereafter, a concrete description will be given.

The voltage is measured at the terminals of the voltage measurement unit VMr, the voltage measurement unit VMp, and the voltage measurement unit VMt of the test device ME. As a result, the following equations are derived.

$$From VMr\_F 1 s = VCCza 1 - Zr$$

$$VCCza 1 = VMr\_F1s + Zr \qquad ( eqa57 )$$

$$From VMp\_F1s = VCCza 1 - Ziau - Zibu - Zp$$

$$VCCza 1 - VMp\_F1s - Zp = Ziau + Zibu \qquad ( eqa 58 )$$

$$From VMt\_F1s = VCCza 1 - Ziau - Zibu - Zt$$

$$VCCza 1 - VMp\_F1s - Zt = Ziau + Zibu \qquad ( eqa59 )$$

$$From ( eqa 58 ) + ( eqa 56 )$$

$$Ziau = \{ ( VCCza 1 - VMp\_F1s - Zp ) + ( VMt\_Fuf - VMt\_Fus ) \} / 2 \qquad ( eqa60 )$$

$$From ( eqa 58 ) - ( eqa 56 )$$

$$Zibu = \{ ( VCCza 1 - VMp\_F1s - Zp ) - ( VMt\_Fuf - VMt\_Fus ) \} / 2 \qquad ( eqa61 )$$

$$From ( eqa 59 ) , ( eqa 60 ) , ( eqa 61 )$$

$$Zt = VCCza 1 - VMt\_F1s - Ziau + Zibu \qquad ( eqa 62 )$$

Note that Ziau and Zibu need to be calculated for each temperature sensor THSu (u=2, 3, 4 . . . ) because the wiring distance to temperature sensor THS1 differs for each temperature sensor THSu.

### Third Test

The third test is to understand the impact of the power supply voltage supplied to each temperature sensor THSu when using the temperature sensor THS1 as a reference.

In the third test, using the two signal lines La and Lb between the temperature sensors THS of the semiconductor device 1, the voltages Vref2, Vptat2, Vref3, Vptat3, Vref4, and Vptat4 are output to the terminals Tr and Tp. The voltages at the terminals Tr and Tp are corrected using the voltage difference obtained in the second test. The voltage values Vref and Vptat of each temperature sensor THS are generated from GND, but the AD conversion value of Vptat based on Vref, and the analog values using Vref and Vptat are not affected as the GND level is offset. Using this, a test is conducted to estimate the impact of the GND level differences due to the location of the temperature sensor THS.

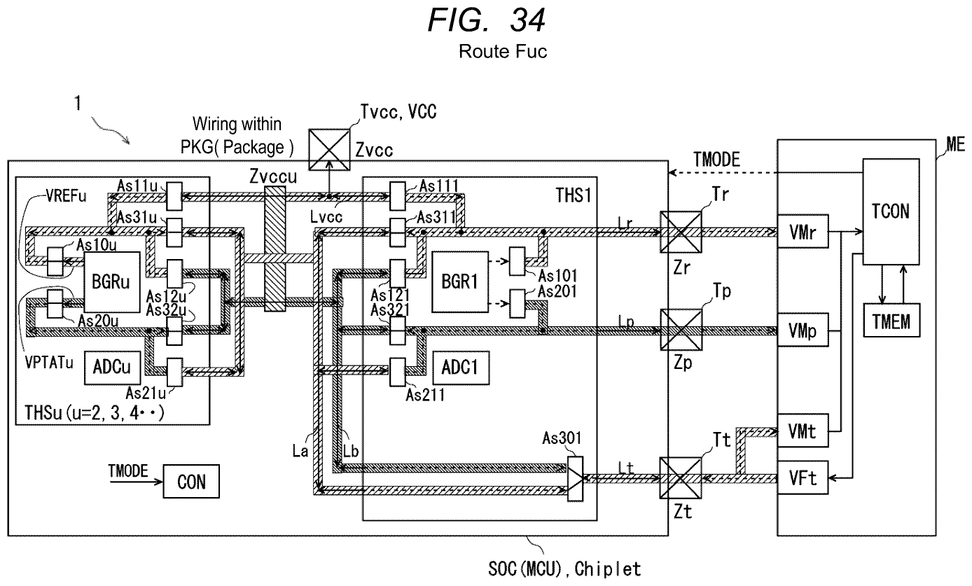

FIG. 34 is a configuration diagram illustrating the semiconductor device 1 according to the first embodiment, showing the route for measuring the reference voltage VREF and the PTAT voltage VPTAT of the temperature sensor THSu. The route shown in FIG. 34 is referred to as route Fuc. As shown in FIG. 34, in the route Fuc, the reference voltage VREFu output from the bandgap reference circuit BGRu of temperature sensor THSu is measured by the voltage measurement unit VMr via terminal Tr. Also, in route Fuc, the PTAT voltage VPTATu output from the bandgap reference circuit BGRu of the temperature sensor THSu is measured by the voltage measurement unit VMp via the terminal Tp. To form this route Fuc, the control unit CON turns on the switches As10u, As20u, As31u, and As32u of the temperature sensor THSu according to the test mode signal TMODE from the test device ME. Additionally, the control unit CON turns on the switches As311 and As321 of the temperature sensor THS1. Thus, the following equations are obtained.

$$VREFu = VMr\_VREFu + Zr α + Ziau \qquad ( eqa 71 )$$

$$VREFu = VMt\_VREFu + Zt α + Ziau \qquad ( eqa 72 )$$

$$VPTATu = VMr\_VPTATu + Zp α + Zibu \qquad ( eqa 73 )$$

Note that although not shown in the figure, the ADC value of PTATu/VREFu is also obtained in the temperature sensor THSu. The voltage drops Zrα, Zpα, Ziau, and Zibu are obtained through the first and second tests. Therefore, by correcting the measurements at the terminals Tr and Tp using the voltage drops Zrα, Zpα, Ziau, and Zibu, the reference voltage VREF and the PTAT voltage VPTAT of the temperature sensor THSu can be obtained accurately. Thus, the deviation of the power supply voltage of the temperature sensor THSu when using the temperature sensor THS1 as a reference can be estimated. Additionally, the rectangular block shown in the figure (signal line between temperature sensors THS) can be adapted not only for the same chip but also for signal lines between chiplets.

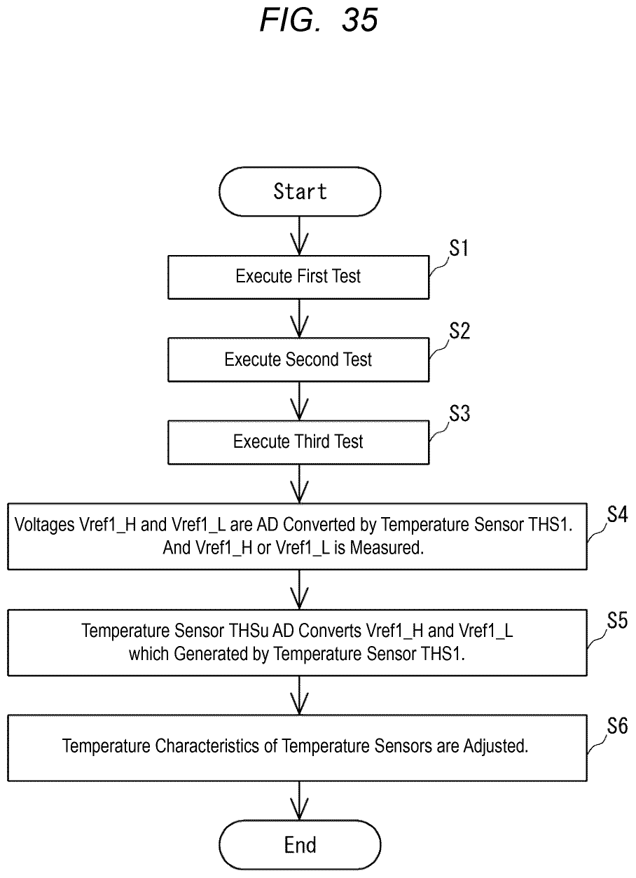

Next, the control method for adjusting the temperature characteristics of the temperature sensor of the semiconductor device 1 in this embodiment will be explained. FIG. 35 is a flowchart illustrating the control method of semiconductor device 1 according to the first embodiment. As shown in FIG. 35, the control method of semiconductor device 1 includes the temperature sensor THS, the terminals Tr, Tp, Tt, and Tvcc, where the terminal Tvcc is coupled to the terminals Tr, Tp, and Tt via the switch As, and the operation of the switch As is controlled by the control unit CON. Then, the control unit CON controls the switch As to execute the aforementioned first to third tests (steps S1 to S3).

Next, a test is executed to obtain the temperature characteristics of each temperature sensor. First, the voltages Vref1_H and Vref1_L generated by the temperature sensor THS1 are AD converted by the temperature sensor THS1. Also, the reference voltage VREF of the temperature sensor THS1 is measured at the terminal Tr, and the voltage Vref1_H or Vref1_L generated by the temperature sensor THS1 is measured at the terminal Tp. (step S4)

Next, the voltages Vref1_H and Vref1_L generated by the temperature sensor THS1 are supplied to the temperature sensor THSu. The temperature sensor THSu performs AD conversion of the voltages Vref1_H and Vref1_L. The temperature sensor THSu measures the voltages VREF and Vptat of the temperature sensor THSu at the terminals Tr and Tp. (step S5)

Based on the values obtained from the first to third tests, the values obtained in steps S4 and S5 are corrected to obtain the temperature characteristics of each temperature sensor THSu from the temperature sensor THS1. Then, the temperature characteristics of the temperature sensor THSu are adjusted based on the temperature characteristics of the temperature sensor THS1.

Next, the effects of this embodiment will be explained. With the improvement of semiconductor device specifications, the temperature sensor THS measuring the temperature of the semiconductor device is desired to have improved measurement accuracy. The voltage value indicating the temperature characteristics output from the temperature sensor THS within the semiconductor device is AD converted and used within the IP of the semiconductor device. Therefore, it is configured so that the user of the semiconductor device does not need to obtain the voltage value output from the temperature sensor THS from external terminals.

The semiconductor device is provided with test terminals for measuring voltage VREF and voltage VPTAT only for temperature sensor THS1 for the purpose of temperature adjustment of the analog temperature characteristics of the temperature sensor. The analog temperature characteristics of the temperature sensor THS1 are obtained based on the voltage measured using these test terminals. The temperature adjustment of the analog temperature characteristics of other temperature sensors THSu is performed based on the temperature characteristics of temperature sensor THS1. However, the analog temperature characteristics of other temperature sensors THSu are not directly measured. Therefore, temperature adjustment is difficult, leading to a decrease in yield.

The semiconductor device 1 of this embodiment is provided with the terminal Tt in addition to the terminals Tr and Tp used for temperature adjustment of the temperature characteristics of the temperature sensor THS1. Also, the terminal Tvcc, into which a predetermined voltage VCC is input, is coupled to the terminals Tr, Tp, and Tt via the switch As. Therefore, by controlling the switch As, the control unit CON can change the route to which the voltage VCC input from the terminal Tvcc and the test voltage input from the terminal Tt are applied, thereby obtaining the voltage drop of each route. As a result, the voltage measured at the test terminal can be corrected for voltage drop, allowing the analog temperature characteristics of each temperature sensor THS to be obtained accurately. As a result, measurement accuracy can be improved.

Additionally, the semiconductor device 1 may include a plurality of temperature sensors THSu and a plurality of signal lines La and Lb coupling each temperature sensor THS. Therefore, the semiconductor device 1 can, for example, loop back the test voltage input from the terminal Tt to the terminals Tr and Tp via the switch As. This allows the temperature characteristics of each temperature sensor THS to be output in analog form. Thus, the measurement accuracy of the temperature sensor THS can be improved. In this case, since the voltage drop of the signal lines La and Lb can be derived, measurement accuracy can be further improved.

As a means to achieve similar effects, it is conceivable to provide an analog-dedicated terminal near each temperature sensor THSu to obtain the analog temperature characteristics of each temperature sensor THSu. However, providing a new analog-dedicated terminal increases cost. In contrast, in this embodiment, the analog temperature characteristics of each temperature sensor THSu can be obtained without increasing costs.

### Modification of the First Embodiment

The temperature sensor THS1 and Each temperature sensor THS1 and THSu, including temperature sensor THS1 included in semiconductor device 1 of the first embodiment, is equipped with a bandgap reference circuit BGR and an AD converter ADC. However, according to the first embodiment, if the voltage drop of the wiring between each temperature sensor THS can be understood, an AD converter ADC may be provided only in one of the temperature sensors THS, and the remaining temperature sensors THS may not be equipped with an AD converter ADC. For example, the reference voltage Vref2 and the PTAT voltage ptat2 output from the temperature sensor THS2 can be supplied to the temperature sensor THS1 via the signal lines La and Lb. The temperature sensor THS1 equipped with an AD converter ADC performs AD conversion based on the reference voltage Vref2 and the PTAT voltage ptat2 from the temperature sensor THS2. At this time, since the voltage drop due to the signal lines La and Lb is known in advance from the test of the first embodiment, by performing AD conversion considering this voltage drop, the temperature detected by the temperature sensor THS2 can be appropriately obtained.

In the temperature sensor, the AD converter ADC is several times larger in area compared to the bandgap reference circuit BGR. Therefore, in a semiconductor device equipped with a plurality of temperature sensors, if the number of AD converters ADC can be reduced, the chip area can be reduced, resulting in cost reduction.

### Second Embodiment

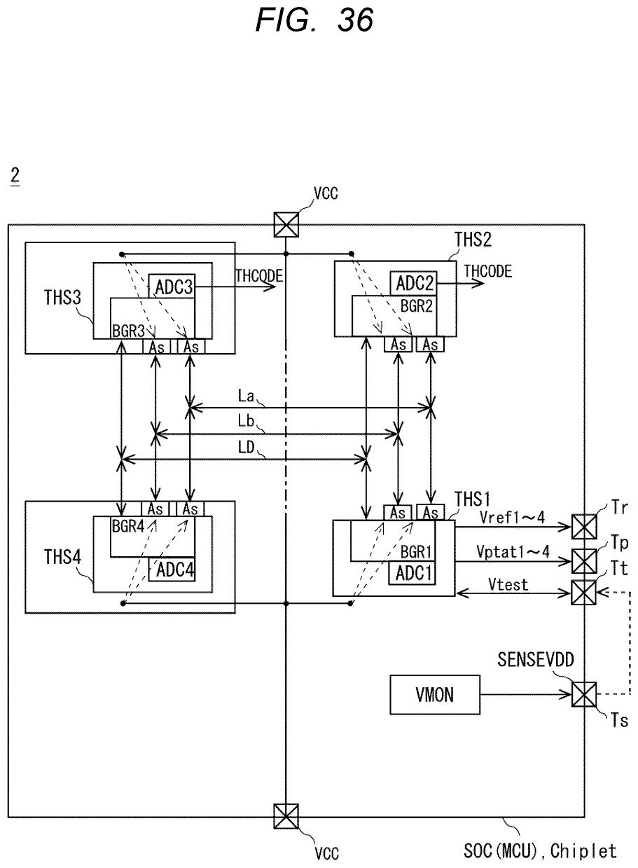

Next, second embodiment will be described. This embodiment is an extension of the application of the first embodiment. FIG. 36 is a configuration diagram illustrating a semiconductor device 2 according to embodiment 2. As shown in FIG. 36, the semiconductor device 2 of this embodiment further includes a terminal Ts and a power supply voltage monitor circuit VMON. The terminal Ts is supplied with a power supply voltage generated by a power IC coupled on a substrate implementing a System on a Chip (SoC) or the like. The power supply voltage monitor circuit VMON detects abnormalities in the power supply voltage VDD by monitoring it via the terminal Ts. The power supply voltage monitor circuit VMON performs AD conversion based on the reference voltage Vref value VREF1 and the sensing voltage SENSEVDD supplied to the terminal Ts. As a result, an AD conversion value as the power supply voltage monitor result is obtained. In the second embodiment, the terminal Ts is coupled to the terminal Tt on a substrate implementing a System on a Chip (SoC) or the like. The voltage applied to the terminal Tt is referred to as voltage Vtest. The voltage Vtest is equal to the sensing voltage SENSEVDD applied to the terminal Ts. The temperature sensor THS1 performs AD conversion based on the voltage Vtest from the terminal Tt and the reference voltage Vref output by the bandgap reference circuit BGR within the temperature sensor THS1. If the AD conversion result of the voltage Vtest from the temperature sensor THS1 is converted to be comparable with the power supply voltage monitor result, it can be confirmed whether the power supply voltage monitor circuit VMON is operating correctly. The following describes the specific usage method.

During preparation, a table for converting the AD conversion values (digital values) obtained by AD converting the voltage values VREF1 and Vtest into the sensing voltage SENSEVDD is prepared in advance. The preparation method includes the following two approaches.

(1) Trimming for the conversion table obtained during production testing is performed. Here, trimming means, for example, writing into a fuse bit. (2) Considering the load of the substrate wiring, trimming for the conversion table that is obtained in the initial test after assembly at the customer's site within the semiconductor device 2 such as a chip is performed. Alternatively, record it in the memory of the customer's system.

The procedure during use is as follows.

(I) In the aging degradation confirmation test of the temperature sensor THS, confirm that the temperature characteristics of the temperature sensor THS have not deteriorated. (II) Next, perform AD conversion of the reference voltage Vref voltage VREF (VREF1) and voltage Vtest to obtain the voltage value of the sensing value SENSEVDD. (III) Next, use the test function of the monitor VMON to test whether the monitor VMON outputs a voltage abnormality before and after the voltage value of the sensing value SENSEVDD. This realizes the performance test of the monitor VMON.

According to this embodiment, by monitoring the power supply voltage VDD in the semiconductor device 2, abnormalities in the power supply voltage VDD can be easily detected.

### Third Embodiment

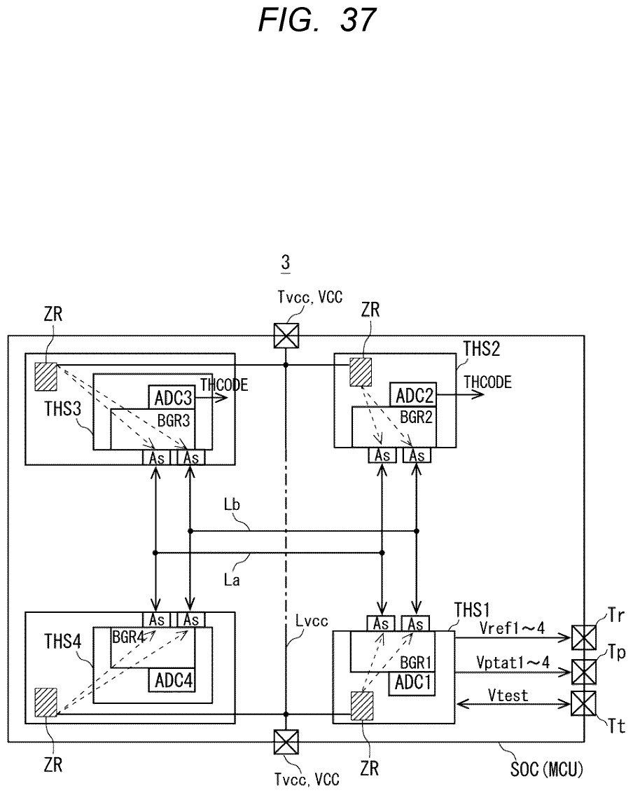

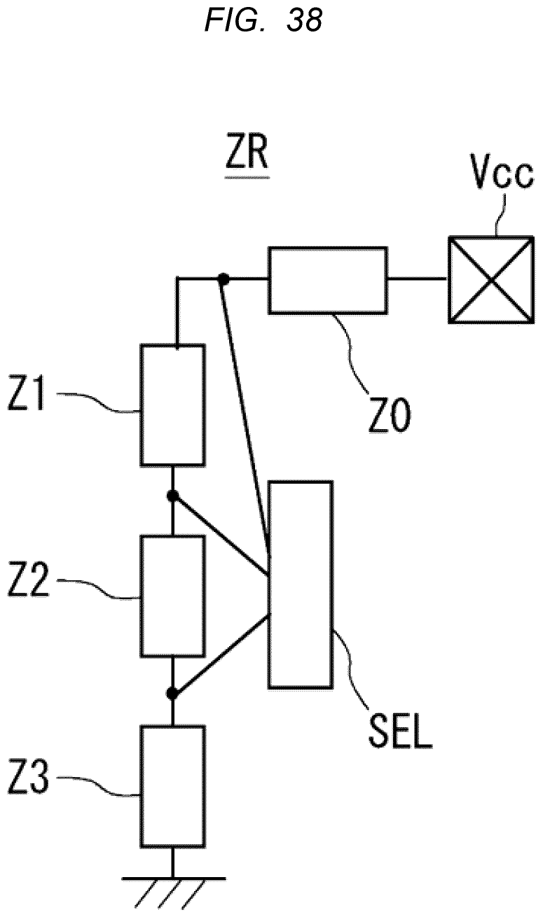

Next, as third embodiment, an application example of the first embodiment will be described. FIG. 37 is a configuration diagram illustrating a semiconductor device 3 according to third embodiment. FIG. 38 is a diagram illustrating a resistor division ZR in the semiconductor device 3 according to third embodiment. As shown in FIGS. 37 and 38, the semiconductor device 3 includes a resistor division ZR. The resistor division ZR includes resistors Z0 to Z3 that cause multiple voltage drops and a switch SEL. By switching the switch SEL, resistors Z0 to Z3 can be selected.

In the aforementioned the first embodiment, a test using voltage VCC is used. Since the wiring routes such as signal lines La and Lb are high-impedance configurations, leakage current causes voltage drops to occur due to elements such as switch As. As a result, the amount of voltage drop varies depending on the magnitude of the voltage value applied to the wiring route.

The operating guaranteed range of temperature sensors THS1 to THS4 corresponds to the normal operating temperature range of the semiconductor device 3. For example, a temperature range of −40 degrees to 125 degrees is assumed. The voltage Vptat of the PTAT voltage ptat at this time is generated by the resistor division ZR from the voltage VCC. Here, the PTAT voltage ptat equivalent to 125 degrees is referred to as voltage Vptat_H, and the PTAT voltage ptat equivalent to −40 degrees is referred to as voltage Vptat_L.

The voltage between Z0 and Z1 is equivalent to the reference voltage Vref

The voltage between Z1 and Z2 is the voltage of Vptat_H

The voltage between Z2 and Z3 is the voltage of Vptat_L

If the amount of voltage drop is not linearly related to the voltage applied to the wiring route, the change in the amount of voltage drop can be understood by increasing the number of resistor divisions.

This is used as voltages VCC1 and VCC2, and tests are conducted for the number of voltages divided by the resistor using switch SEL.

In the above tests, when using the reference voltage Vref and the PTAT voltage ptat of the bandgap reference circuit BGR for each temperature sensor THS actually used, the values measured at the terminals Tr and Tp are corrected to accurately estimate the voltage value of the bandgap reference circuit BGR used during AD conversion.

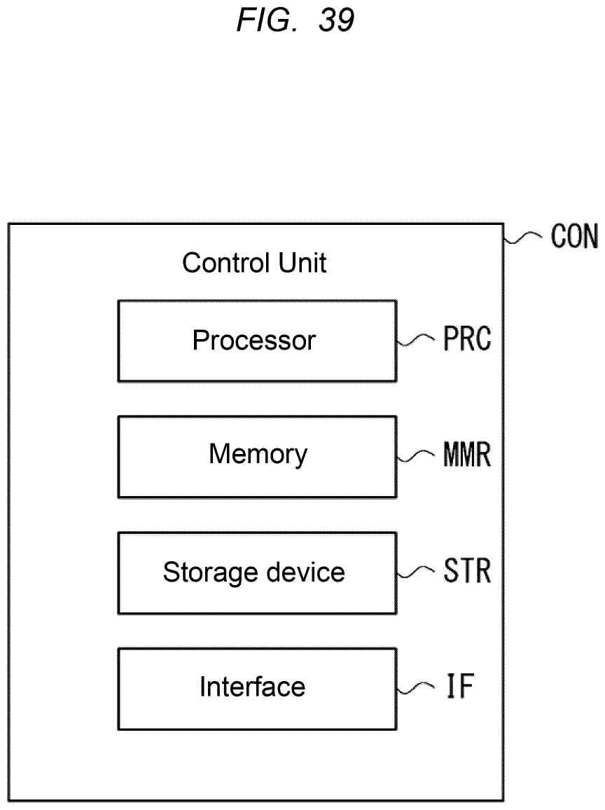

FIG. 39 is a block diagram illustrating a control unit CON in semiconductor devices 1 to 3 according to first to third embodiments. As shown in FIG. 39, the control unit CON may include an information processing device such as a microcomputer. The control unit CON may further include a processor PRC, memory MMR, storage device STR, and interface IF.

The storage device STR stores programs describing the processes executed by each configuration of the control unit CON. The processor PRC reads the program from the storage device STR into the memory MMR and executes the program. This allows the processor PRC to realize the functions of each configuration in the control unit CON. The interface IF connects with other parts and performs data input and output.

Each configuration of the control unit CON may be realized by dedicated hardware. Additionally, some or all of the components may be realized by general-purpose or dedicated circuits, processor PRC, or combinations thereof. These may be configured by a single chip or by multiple chips connected via a bus. Some or all of the components may be realized by a combination of the aforementioned circuits and programs. The processor PRC may be a CPU, GPU, FPGA, quantum processor (quantum computer control chip), or the like.

If some or all of the components of the control unit CON are realized by multiple information processing devices or circuits, these devices or circuits may be centrally or distributedly arranged. For example, information processing devices or circuits may be realized in a form where each is connected via a communication network NW by a client-server system, cloud computing system, or the like. The functions of the control unit CON may also be provided in a SaaS (Software as a Service) format.

Although the present disclosure has been specifically described based on the embodiments, it is needless to say that the present disclosure is not limited to comparative examples, embodiments, and modified examples, and various modifications can be made without departing from the gist thereof. For example, combinations of the configurations of the comparative example, embodiments 1 to 3, and the comparative example are also within the scope of the technical idea of the embodiments. Additionally, the following control methods for semiconductor devices are also within the scope of the technical idea of the embodiments.

### (Clauses A)

Clause A1. A method of controlling semiconductor device, the semiconductor device having a first temperature sensor which includes first to fourth terminals and first to fourth switch units, the first temperature sensor having a bandgap reference circuit, the first switch unit being configured to output a reference voltage generated based on the output of the bandgap reference circuit from the first terminal, the second switch unit being configured to output a PTAT voltage generated based on the output of the bandgap reference circuit, the third switch unit being configured to couple between the third terminal and the first or the second terminal, and the fourth switch unit being configured to output a predetermined voltage supplied to the first temperature sensor from the first to third terminals, the method comprising:
controlling the operation of the first to fourth switch units by a control unit.

Clause A2. The method according to clause A1, wherein the semiconductor device includes a first wiring connecting the first temperature sensor and the first terminal, a second wiring connecting the first temperature sensor and the second terminal, a third wiring connecting the first temperature sensor and the third terminal, and a fourth wiring connecting the first temperature sensor and the fourth terminal, wherein the fourth wiring is connected to the first wiring, the second wiring, and the third wiring via the fourth switch unit.

Clause A3. The method according to clause A1, wherein the first temperature sensor includes a bandgap reference circuit, the first terminal is connected to output the reference voltage of the bandgap reference circuit, and the second terminal is connected to output the PTAT voltage of the bandgap reference circuit.

Clause A4. The method according to clause A1, wherein the the controlling by the control unit includes outputting, from the first terminal, a voltage including a first voltage drop by the first terminal to a voltage which is input from the fourth terminal.

Clause A5. The method according to clause A1, wherein the controlling by the control unit includes outputting, from the second terminal, a voltage including a second voltage drop by the second terminal to the voltage input from the fourth terminal.

Clause A6. The method according to clause A1, wherein the controlling by the control unit includes outputting, from the third terminal, a voltage including a third voltage drop by the third terminal to the voltage input from the fourth terminal.

Clause A7. The method according to clause A1, wherein the controlling by the control unit includes outputting, from the first terminal, a voltage including a third voltage drop by the third terminal to the first test voltage input from the third terminal.

Clause A8. The method according to clause A1, wherein the controlling by the control unit includes outputting, from the second terminal, a voltage including a third voltage drop by the third terminal to the second test voltage input from the third terminal.

Clause A9. The method according to clause A1, wherein the semiconductor device further includes a second temperature sensor including fifth to eighth switch units, a first signal line coupling the first temperature sensor and the second temperature sensor, and a second signal line coupling the first temperature sensor and the second temperature sensor, wherein the control unit controls the operation of the fifth to eighth switch units.

Clause A10. The method according to clause A9, wherein the controlling by the control unit includes outputting, from the first terminal, a voltage including a fourth voltage drop by the first signal line and the first terminal to the voltage input from the fourth terminal.

Clause A11. The method according to clause A9, wherein the controlling by the control unit includes outputting, from the third terminal, a voltage including a fifth voltage drop by the second signal line and the third terminal to the voltage input from the fourth terminal.

Clause A12. The method according to clause A9, wherein the controlling by the control unit includes outputting, from the second terminal, a voltage including a sixth voltage drop by the second signal line and the second terminal to the voltage input from the fourth terminal.

Clause A13. The method according to clause A19, wherein the controlling by the control unit includes outputting, from the third terminal, a voltage including a seventh voltage drop by the first signal line and the third terminal to the voltage input from the fourth terminal.

Clause A14. The method according to Clause A9, wherein the controlling by the control unit includes outputting, from the first terminal, a voltage including an eighth voltage drop by the second signal line and a third voltage drop by the third terminal with respect to the third test voltage input from the third terminal.

Clause A15. The method according to Clause A9, wherein the controlling by the control unit includes outputting, from the second terminal, a voltage including a ninth voltage drop by the first signal line and a third voltage drop by the third terminal f to the fourth test voltage input from the third terminal

The following semiconductor device control program, which executes the semiconductor device control method on a computer, is also within the scope of the technical concept of the embodiment. Such a program may be stored and provided to a computer using various types of non-transitory computer-readable media. Non-transitory computer-readable media include various types of tangible storage media. Examples of non-transitory computer-readable media include magnetic recording media (e.g., flexible disks, magnetic tapes, hard disk drives), magneto-optical recording media (e.g., magneto-optical disks), CD-ROM (Read Only Memory), CD-R, CD-R/W, solid-state memories (e.g., masked ROM, PROM (Programmable ROM), EPROM (Erasable PROM), flash ROM, RAM (Random Access Memory)). The program may also be supplied to the computer by various types of transitory computer-readable media. Examples of transitory computer-readable media include electrical signals, optical signals, and electromagnetic waves. The transitory computer-readable medium may provide the program to the computer via wired or wireless communication paths, such as electrical wires and optical fibers.

### (Clauses B)

Clause B1. A semiconductor device control program for controlling a semiconductor device, the semiconductor device having a first temperature sensor which includes first to fourth terminals and first to fourth switch units, the first temperature sensor having a bandgap reference circuit, the first switch unit being configured to output a reference voltage generated based on the output of the bandgap reference circuit from the first terminal, the second switch unit being configured to output a PTAT voltage generated based on the output of the bandgap reference circuit, the third switch unit being configured to connect between the third terminal and the first or second terminal, and the fourth switch unit being configured to output a predetermined voltage supplied to the first temperature sensor from the first to third terminals, the semiconductor device control program causing the semiconductor device to perform to steps of:
controlling the operation of the first to fourth switch units.

Clause B2. The semiconductor device control program according to Clause B1, wherein the semiconductor device includes a first wiring connecting the first temperature sensor and the first terminal, a second wiring connecting the first temperature sensor and the second terminal, a third wiring connecting the first temperature sensor and the third terminal, and a fourth wiring connecting the first temperature sensor and the fourth terminal, wherein the fourth wiring is connected to the first wiring, the second wiring, and the third wiring via the predetermined switch.

Clause B3. The semiconductor device control program according to Clause B1, wherein the first temperature sensor includes a bandgap reference circuit, the first terminal is connected to output the reference voltage of the bandgap reference circuit, and the second terminal is connected to output the PTAT voltage of the bandgap reference circuit.

Clause B4. The semiconductor device control program according to Clause B1, wherein the controlling includes outputting, from the first terminal, a voltage including a first voltage drop by the first terminal to the voltage input from the fourth terminal.

Clause B5. The semiconductor device control program according to Clause B1, wherein the controlling includes outputting, from the second terminal, a voltage including a second voltage drop by the second terminal to the voltage input from the fourth terminal.

Clause B6. The semiconductor device control program according to Clause B1, wherein the controlling includes outputting, from the third terminal, a voltage including a third voltage drop by the third terminal to the voltage input from the fourth terminal.

Clause B7. The semiconductor device control program according to Clause B1, wherein the controlling includes outputting, from the first terminal, a voltage including a third voltage drop by the third terminal to the first test voltage input from the third terminal.

Clause B8. The semiconductor device control program according to Clause B1, wherein the controlling includes outputting, from the second terminal, a voltage including a third voltage drop by the third terminal to the second test voltage input from the third terminal.

Clause B9. The semiconductor device control program according to Clause B1, wherein the semiconductor device further includes a second temperature sensor including a plurality of switches, a first signal line coupling the first temperature sensor and the second temperature sensor, and a second signal line coupling the first temperature sensor and the second temperature sensor.

Clause B10. The semiconductor device control program according to Clause B9, wherein the controlling includes outputting, from the first terminal, a voltage that includes a fourth voltage drop caused by the first signal line and the first terminal to the voltage input from the fourth terminal.

Clause B11. The semiconductor device control program according to Clause B9, wherein the controlling includes outputting, from the third terminal, a voltage that includes the fifth voltage drop caused by the second signal line and the third terminal to the voltage input from the fourth terminal.

Clause B12. The semiconductor device control program according to Clause B9, wherein the controlling includes outputting from the second terminal a voltage that includes the sixth voltage drop caused by the second signal line and the second terminal to the voltage input from the fourth terminal.

Clause B13. The semiconductor device control program according to Clause B9, wherein the controlling includes outputting from the third terminal a voltage that includes the seventh voltage drop caused by the first signal line and the third terminal to the voltage input from the fourth terminal.

Clause B14. The semiconductor device control program according to Clause B9, wherein the controlling includes outputting from the first terminal a voltage that includes the eighth voltage drop caused by the second signal line and the third voltage drop caused by the third terminal to the third test voltage input from the third terminal.

Clause B15. The semiconductor device control program according to Clause B9, wherein the controlling includes outputting from the second terminal a voltage that includes the ninth voltage drop caused by the first signal line and the third voltage drop caused by the third terminal to the fourth test voltage input from the third terminal.

### (Clauses C)

Clause C1. A test method for a semiconductor device, the semiconductor device comprising a first temperature sensor, a control unit for controlling the first temperature sensor, and first to third terminals, the first temperature sensor including a first bandgap reference circuit, a first analog-to-digital conversion circuit, a first switch unit, a second switch unit, a third switch unit, a fourth switch unit and a control unit, the first bandgap reference circuit being configured to output a first reference voltage and a first detection voltage with a primary linear temperature dependency, the first analog-to-digital conversion circuit being configured to convert the first detection voltage from an analog value to a digital value based on the first reference voltage, the first switch unit being provided to output the first reference voltage from the first terminal, the second switch unit being provided to output the first detection voltage from the second terminal, the third switch unit being provided between the third terminal and the first and second terminals, and the fourth switch unit being provided to output the power supply voltage to either the first or third terminal, and the control unit being provided to control the first to fourth switch units, the test method comprising:
a first measurement step of controlling the third and the fourth switch unit to output the power supply voltage from the first terminal and to obtain a first measurement voltage at the first terminal;
a second measurement step of controlling the third and fourth switch units to output the power supply voltage from the second terminal and to obtain a second measurement voltage at the second terminal;
a third measurement step of including controlling the third switch unit to output the voltage supplied to the third terminal from the first terminal and to measure a third measurement voltage of the third terminal when the first measurement voltage is obtained from the first terminal;
a fourth measurement step of including controlling the third switch unit to output the voltage supplied to the third terminal from the second terminal and to measure the fourth measurement voltage of the third terminal when the second measurement voltage is obtained from the second terminal, and
calculating the measurement error of the first terminal based on the first and the third measurement voltage and the measurement error of the second terminal based on the second measurement voltage and the fourth measurement voltage.

Clause C2. The test method according to Clause C1, wherein the semiconductor device further includes a second temperature sensor, and a first and a second signal line which are provided to couple the first and second temperature sensors to each other and couple to the third switch unit,
wherein the second temperature sensor includes a second bandgap reference circuit which outputs a second reference voltage and a second detection voltage with a primary linear temperature dependency, a second analog-to-digital conversion circuit which converts the second detection voltage from an analog value to a digital value based on the second reference voltage, a fifth switch unit which is connected to the second reference voltage output of the second temperature sensor, a sixth switch unit which is connected to the second detection voltage output of the second temperature sensor, a seventh switch unit which is connected between the first signal line and the second signal line and an eighth switch unit which is connected between the terminal supplying the power supply voltage and the seventh switch unit, and
wherein the test method includes:
a fifth measurement step of controlling the third, seventh, and eighth switch units to measure the power supply voltage at the first terminal via the first signal line and to measure the power supply voltage at the third terminal via the second signal line,
a sixth measurement step of controlling the third, seventh, and eighth switch units to measure the power supply voltage at the second terminal via the second signal line and to measure the power supply voltage at the third terminal via the first signal line,
a seventh measurement step of controlling the third and seventh switch units to measure the voltage supplied to the third terminal at the first terminal via the first signal line and the second signal line in order,
an eighth measurement step of controlling the third and seventh switch units to measure the voltage supplied to the third terminal at the second terminal via the second signal line and the first signal line in order, and
a second calculation step of calculating the voltage drop of the first signal line and the second signal line based on the voltages measured in the fifth to the eighth measurement step.

What is claimed is:

1. A semiconductor device comprising:
a first, a second, a third and a fourth terminal; and
a first temperature sensor including a first, a second, a third and a fourth switch unit,
wherein the first temperature sensor has a bandgap reference circuit,
wherein the first switch unit is configured to output a reference voltage generated based on the output of the bandgap reference circuit from the first terminal,
wherein the second switch unit is configured to output a PTAT voltage generated based on the output of the bandgap reference circuit,
wherein the third switch unit is configured to couple between the third terminal and at least one of the first and the second terminal, and
wherein the fourth switch unit is configured to output, from the first, the second and the third terminal, a predetermined voltage supplied to the first temperature sensor.

2. The semiconductor device according to claim 1, further comprising:
a first wiring connecting the first temperature sensor and the first terminal;
a second wiring connecting the first temperature sensor and the second terminal;
a third wiring connecting the first temperature sensor and the third terminal; and
a fourth wiring connecting the first temperature sensor and the fourth terminal,
wherein the fourth wiring is coupled to the first, the second and third wiring via the fourth switch unit.

3. The semiconductor device according to claim 1,
wherein the first terminal is capable of outputting the reference voltage, and the second terminal is capable of outputting the PTAT voltage.

4. The semiconductor device according to claim 1, further comprising:
a control unit for controlling the operation of the first to the fourth switch units.

5. The semiconductor device according to claim 4, wherein the control unit controls to output, from the first terminal, a voltage including the first voltage drop by the first terminal to the voltage input from the fourth terminal.

6. The semiconductor device according to claim 4, wherein the control unit controls to output from the second terminal a voltage including the second voltage drop by the second terminal to the voltage input from the fourth terminal.

7. The semiconductor device according to claim 4, wherein the control unit controls to output, from the third terminal, a voltage including the third voltage drop by the third terminal to the voltage input from the fourth terminal.

8. The semiconductor device according to claim 4, wherein the control unit controls to output, from the first terminal, a voltage including the third voltage drop by the third terminal to the first test voltage input from the third terminal.

9. The semiconductor device according to claim 4, wherein the control unit controls to output, from the second terminal, a voltage including the third voltage drop by the third terminal to the second test voltage input from the third terminal.

10. The semiconductor device according to claim 1, further comprising:
a second temperature sensor including fifth to eighth switch units,
a first signal line coupling the first and second temperature sensors,
a second signal line coupling the first and second temperature sensors, and
a control unit for controlling the operation of the first to eighth switch units,
wherein the second temperature sensor has a second bandgap reference circuit,
wherein the fifth switch unit is provided to output a second reference voltage generated based on the output of the second bandgap reference circuit from the first terminal, the sixth switch unit is provided to output a second PTAT voltage generated based on the output of the second bandgap reference circuit, the seventh switch unit is provided to connect between the third terminal and either the first or second terminal, and the eighth switch unit is provided to output a predetermined voltage supplied to the second temperature sensor from the first to third terminals.

11. The semiconductor device according to claim 10, wherein the control unit controls to output, from the first terminal, a voltage including the fourth voltage drop by the first signal line and the first terminal to the voltage input from the fourth terminal.

12. The semiconductor device according to claim 10, wherein the control unit controls to output, from the third terminal, a voltage including the fifth voltage drop by the second signal line and the third terminal to the voltage input from the fourth terminal.

13. The semiconductor device according to claim 10, wherein the control unit controls to output, from the second terminal, a voltage including the sixth voltage drop by the second signal line and the second terminal to the voltage input from the fourth terminal.

14. The semiconductor device according to claim 10, wherein the control unit controls to output, from the third terminal, a voltage including the seventh voltage drop by the first signal line and the third terminal to the voltage input from the fourth terminal.

15. The semiconductor device according to claim 10, wherein the control unit controls to output, from the first terminal, a voltage including the eighth voltage drop by the second signal line and the third voltage drop by the third terminal to the third test voltage input from the third terminal.

16. The semiconductor device according to claim 10, wherein the control unit controls to output, from the second terminal, a voltage including the ninth voltage drop by the first signal line and the third voltage drop by the third terminal to the fourth test voltage input from the third terminal.

17. A method of controlling a semiconductor device, the semiconductor device including first to fourth terminals and a first temperature sensor, the first temperature sensor including a bandgap reference circuit and first to fourth switch units, the first switch unit being configured to output a reference voltage generated based on the output of the bandgap reference circuit from the first terminal, the second switch unit being configured to output a PTAT voltage generated based on the output of the bandgap reference circuit, the third switch unit being configured to connect between the third terminal and the first terminal or the second terminal, and the fourth switch unit being configured to output a predetermined voltage supplied to the first temperature sensor from the first to third terminals, the method controlling the semiconductor device comprising:
controlling the operation of the first to fourth switch units by a control unit.

18. A control program of a semiconductor device, the semiconductor device including first to fourth terminals and a first temperature sensor, the first temperature sensor including a bandgap reference circuit and first to fourth switch units, the first switch unit being configured to output a reference voltage generated based on the output of the bandgap reference circuit from the first terminal, the second switch unit being configured to output a PTAT voltage generated based on the output of the bandgap reference circuit, the third switch unit being configured to connect between the third terminal and the first terminal or the second terminal, and the fourth switch unit being configured to output a predetermined voltage supplied to the first temperature sensor from the first to third terminals, the control program of the semiconductor device that causes the semiconductor device to perform to steps of:
controlling the operation of the first to fourth switch units.
